(19) United States
(12) Patent Application Publication
(10) Pub. No.: US 2026/0059712 A1
(43) Pub. Date: Feb. 26, 2026

(54) Liquid Cooling Unit, Control Method, and Liquid Cooling System

(71) Applicant: SANHUA GREEN ENERGY THERMAL MANAGEMENT TECHNOLOGY (HANGZHOU) CO., LTD, Zhejiang (CN)

(72) Inventors: Qiang Gao, Zhejiang (CN); Feng Wang, Zhejiang (CN); Rongrong Zhang, Zhejiang (CN)

(21) Appl. No.: 19/103,042

(22) PCT Filed: Jul. 3, 2023
(86) PCT No.: PCT/CN2023/105567

§ 371 Date: Feb. 11, 2025

(30) Foreign Application Priority Data
Aug. 11, 2022 (CN) 202210962006.1

(51) Int. Cl. H05K 7/20

(52) U.S. Cl. CPC H05K 7/20381; H05K 7/20327; H05K 7/20354

(57) ABSTRACT

A liquid cooling unit, a liquid cooling system having the liquid cooling unit, and a control method for the liquid cooling unit. The liquid cooling unit comprises a first heat exchange assembly, a second heat exchange assembly, a temperature control assembly, and a multi-way valve. The first heat exchange assembly is used for heat exchange with a first device to be temperature-controlled, and the second heat exchange assembly is used for heat exchange with a second device to be temperature-controlled. Each of the first heat exchange assembly, the second heat exchange assembly, and the temperature control assembly is connected to the multi-way valve so as to realize the conversion of a plurality of working modes by means of the reversing of the multi-way valve.

### CROSS-REFERENCE TO RELATED APPLICATION

The application is the U.S. national phase of PCT Application No. PCT/CN2023/105567 filed on Jul. 3, 2023, which claims a priority to and benefits of Chinese Patent Applications No. 202210962006.1, filed with the State Intellectual Property Office of P.R. China on Aug. 11, 2022, the entire contents of which are incorporated herein by reference.

### FIELD

The present disclosure relates to the field of a thermal management technology, specifically to a liquid cooling unit and a liquid cooling system including the same, and to a method for controlling a liquid cooling unit.

### BACKGROUND

As seasons and usage stages change, a temperature demand between a device to be temperature-controlled and an external ambient temperature will also change. In the related art, once a refrigeration assembly is fixedly connected to the device to be temperature-controlled, it is often impossible to change a flow of a cooling gas or liquid inside the refrigeration assembly, resulting in high power consumption during usage.

### SUMMARY

The present disclosure aims to at least partially solve one of the technical problems in the related art. For this, the present disclosure proposes in embodiments a liquid cooling unit, which is advantageous in reduced energy consumption and convenient installation and maintenance.

The present disclosure also proposes in embodiments a liquid cooling system.

The present disclosure also proposes in embodiments a method for controlling a liquid cooling unit.

In embodiments of the present disclosure, the liquid cooling unit includes a first heat exchange assembly, a second heat exchange assembly, a temperature control assembly, and a multi-way valve.

The first heat exchange assembly is configured to heat exchange with a first device to be temperature-controlled; the second heat exchange assembly is configured to heat exchange with a second device to be temperature-controlled; the first heat exchange assembly, the second heat exchange assembly and the temperature control assembly each are connected to the multi-way valve, to achieve switching between multiple operation modes by switching of the multi-way valve.

The liquid cooling unit according to embodiments of the present disclosure is advantageous in reduced energy consumption and convenient installation and maintenance.

In some embodiments, the temperature control assembly includes a first refrigeration assembly and a second refrigeration assembly;
wherein the liquid cooling unit is provided with a first operation mode, a second operation mode, and a third operation mode; and the liquid cooling unit is configured to switch between the first operation mode, the second operation mode, and the third operation mode via the multiple-way valve, wherein
in the first operation mode, the first heat exchange assembly is connected to the second heat exchange assembly in series, at least one of the second refrigeration assembly and the first refrigeration assembly is connected to the first heat exchange assembly and the second heat exchange assembly via the multiple-way valve to form a refrigeration loop;
in the second operation mode, the first refrigeration assembly is connected to the first heat exchange assembly via some ports of the multi-way valve to form a first loop, and/or the second refrigeration assembly is connected to the second heat exchange assembly via other ports of the multi-way valve to form a second loop;
in the third operation mode, the first heat exchange assembly and the second heat exchange assembly form a self-heating circulation loop.

In some embodiments, the temperature control assembly further includes a third refrigeration assembly; in the first operation mode, at least one of the second refrigeration assembly, the first refrigeration assembly and the third refrigeration assembly is connected to the first heat exchange assembly and the second heat exchange assembly to form a refrigeration loop.

In some embodiments, the temperature control assembly further includes a third refrigeration assembly; in the second operation mode, the first refrigeration assembly and the third refrigeration assembly are connected to the first heat exchange assembly via the multi-way valve in sequence to form a third loop, and the second refrigeration assembly is connected to the second heat exchange assembly via the multi-way valve in sequence to form a fourth loop.

In some embodiments, the first refrigeration assembly is connected to the first heat exchange assembly via the multi-way valve in sequence to form a fifth loop, and the second refrigeration assembly and the third refrigeration assembly are connected to the second heat exchange assembly via the multi-way valve in sequence to form a sixth loop.

In some embodiments, at least one of the second refrigeration assembly, the first refrigeration assembly and the third refrigeration assembly is connected to the first heat exchange assembly and the second heat exchange assembly to form multiple refrigeration loops, which are switchable via the multi-way valve.

In some embodiments, the first loop and the second loop are switchable to the third loop and the fourth loop via the multi-way valve; or the first loop and the second loop are switchable to the fifth loop and the sixth loop via the multi-way valve.

In some embodiments, the third loop and the fourth loop form a first loop set; the fifth loop and the sixth loop form a second loop set; and the first loop set and the second loop set are switchable to each other via a core of the multi-way valve.

In some embodiments, the multi-way valve include a house and a core arranged inside the house; the house is provided with a plurality of ports; the first heat exchange assembly, the second heat exchange assembly, and the temperature control assembly each are connected to respective ports correspondingly, to change a flow direction of a refrigerant by switching of the core.

In some embodiments, in the second operation mode, the multi-way valve includes a first multi-way valve; the first multi-way valve is provided with a first port, a second port, a third port, a fourth port, a fifth port, a sixth port, a seventh port, and an eighth port; and the liquid inlet of the first heat exchange assembly, the liquid outlet of the first heat exchange assembly, the liquid inlet of the second heat exchange assembly, the liquid outlet of the second heat exchange assembly, the liquid inlet of the first refrigeration assembly, the liquid outlet of the first refrigeration assembly, the liquid inlet of the second refrigeration assembly, and the liquid outlet of the second refrigeration assembly are correspondingly connected to respective ports of the first multi-way valve.

In some embodiments, in the second operation mode, the multi-way valve is provided with a first port, a second port, a third port, a fourth port, a fifth port, a sixth port, a seventh port, an eighth port, a ninth port, and a tenth port; and the liquid inlet of the first heat exchange assembly, the liquid outlet of the first heat exchange assembly, the liquid inlet of the second heat exchange assembly, the liquid outlet of the second heat exchange assembly, the liquid inlet of the first refrigeration assembly, the liquid outlet of the first refrigeration assembly, the liquid inlet of the second refrigeration assembly, and the liquid outlet of the second refrigeration assembly are correspondingly connected to respective ports of the first multi-way valve.

In some embodiments, in the second operation mode, the multi-way valve includes a first multi-way valve and a second multi-way valve; one port of the first multi-way valve is connected to a liquid inlet of the first refrigeration assembly via a joint pipe; the second multi-way valve is arranged at the joint pipe, so that at least one of the first refrigeration assembly and the third refrigeration assembly is connected to the first heat exchange assembly in sequence to form respective parallel connected loops by switching of the second multi-way valve.

In some embodiments, the first multi-way valve is provided with a first port, a second port, a third port, a fourth port, a fifth port, a sixth port, a seventh port, and an eighth port; the second multi-way valve is a three-way valve; the three-way valve is provided with a first liquid-inlet port, a first liquid outlet and a second liquid outlet; the first port is connected to the liquid inlet of the first refrigeration assembly via the joint pipe; the second multi-way valve is arranged at the joint pipe, the first liquid-inlet port is connected to the first port, the first liquid outlet is connected to a liquid inlet of the third refrigeration assembly, the second liquid outlet is connected to the liquid inlet of the first refrigeration assembly, so that at least one of the first refrigeration assembly and the third refrigeration assembly is connected to the first heat exchange assembly by switching-on/off each of the first liquid-inlet port, the first liquid outlet and the second liquid outlet.

In some embodiments, the first refrigeration assembly is a compression refrigeration assembly, the second refrigeration assembly is a first dry cooler assembly, and the third refrigeration assembly is a second dry cooler assembly.

In some embodiments, the compression refrigeration assembly includes a condensation pipeline, a plate heat exchanger, a compressor, a first condenser, a first expansion valve, and a first heat exchange pipeline; wherein the plate heat exchanger, the compressor, the first condenser, and the first expansion valve are sequentially arranged at the condensation pipeline in a direction along which a condensation gas flows in the condensation pipeline and form a refrigeration circulation loop correspondingly; and the first heat exchange pipeline is connected to the plate heat exchanger and the multi-way valve to form a heat dissipation circulation loop.

In some embodiments, the liquid cooling unit is further provided with a fourth operation mode, the temperature control assembly further includes a heater; wherein in the fourth operation mode, the heater is connected to the first heat exchange assembly and/or the second heat exchange assembly via the multi-way valve to achieve heating of a corresponding device to be temperature-controlled, so that the liquid cooling unit is allowed to switch between the first operation mode, the second operation mode, the third operation mode, and the fourth operation mode.

In some embodiments, the temperature control assembly includes a heat pump assembly, wherein the heat pump assembly includes a condensation end and an evaporation end, wherein the condensation end and the evaporation end each are connected to respective ports of the multi-way valve, wherein the condensation end is connected to the first heat exchange assembly and/or the second heat exchange assembly via the multi-way valve to form a heat pump heating loop; or
the evaporation end is connected to the first heat exchange assembly and/or the second heat exchange assembly via the multi-way valve to form a heat pump refrigeration loop, wherein the heat pump heating loop and the heat pump refrigeration loop are switchable to each other.

In some embodiments, the first dry cooler assembly includes a first dry cooler liquid-inlet pipe, a first dry cooler body, and a first dry cooler liquid-outlet pipe; a liquid inlet of the first dry cooler liquid-inlet pipe is connected to a liquid outlet of the multi-way valve; a liquid outlet of the first dry cooler liquid-inlet pipe is connected to a liquid inlet of the first dry cooler body; a liquid outlet of the first dry cooler body is connected to a liquid inlet of the first dry cooler liquid-outlet pipe; and a liquid outlet of the first dry cooler liquid-outlet pipe is connected to a liquid inlet of the multi-way valve.

In some embodiments, the second dry cooler assembly includes a second dry cooler liquid-inlet pipe, a second dry cooler body, and a second dry cooler liquid-outlet pipe; a liquid inlet of the second dry cooler liquid-inlet pipe is connected to a liquid outlet of the multi-way valve; a liquid outlet of the second dry cooler liquid-inlet pipe is connected to a liquid inlet of the second dry cooler body; a liquid outlet of the second dry cooler body is connected to a liquid inlet of the second dry cooler liquid-outlet pipe; and a liquid outlet of the second dry cooler liquid-outlet pipe is connected to a liquid inlet of the multi-way valve.

In some embodiments, the liquid cooling unit further includes a condenser bypass assembly connected to the temperature control assembly.

In some embodiments, the condenser bypass assembly includes a condenser bypass pipeline, a second expansion valve, a dehumidifying evaporator, and a dehumidifying fan; the second expansion valve and the dehumidifying evaporator are arranged at the condenser bypass pipeline; an air inlet of the condenser bypass pipeline is arranged at a pipeline between the condenser and the first expansion valve; and the dehumidifying fan is arranged opposite to the dehumidifying evaporator.

In some embodiments, the liquid cooling unit further includes a first fan, wherein the first fan is arranged to correspond to each of respective evaporators of the first refrigeration assembly, the second refrigeration assembly, and the third refrigeration assembly.

In some embodiments, the liquid cooling unit further includes a first fan and a second fan, wherein the first fan is arranged to correspond to one of respective evaporators of the first refrigeration assembly, the second refrigeration assembly, and the third refrigeration assembly; and the second fan is arranged to correspond to other two of respective evaporators of the first refrigeration assembly, the second refrigeration assembly and the third refrigeration assembly

In some embodiments, the liquid cooling unit further includes a first fan, a second fan, and a third fan, which are arranged to correspond to the first refrigeration assembly, the second refrigeration assembly, and the third refrigeration assembly in one-to-one correspondence.

In some embodiments, a cut-off valve is arranged between at least one of the compression refrigeration assembly, the first dry cooler assembly, and the second dry cooler assembly, and the multi-way valve.

In some embodiments, the first heat exchange assembly includes a first heat exchange pipe, a first heat exchanger body, and a first pump body; both the first heat exchanger body and the first pump body are arranged at the first heat exchange pipe; and the first heat exchange pipe is circularly connected to the multi-way valve; the second heat exchange assembly includes a second heat exchange pipe, a second heat exchanger body, and a second pump body; both the second heat exchanger body and the second pump body are arranged at the second heat exchange pipe; and the second heat exchange pipe is circularly connected to the multi-way valve.

The present disclosure provides in embodiments a method for controlling a liquid cooling unit, the method including acquiring an external ambient temperature; acquiring a temperature of the first heat exchange assembly and/or a temperature of the second heat exchange assembly; and switching an operation mode via a multi-way valve.

In some embodiments, the external ambient temperature is T₀; the temperature of the first heat exchange assembly is T₁; the temperature of the second heat exchange assembly is T₂; a temperature control assembly includes a compression refrigeration assembly, a first dry cooler assembly and a second dry cooler assembly;
based on T₀−T₁≥a preset value A₁, and T₂−T₀≥a preset value B₁, the compression refrigeration assembly is connected to the first heat exchange assembly, and at least one of the first dry cooler assembly and the second dry cooler assembly is connected to the second heat exchange assembly;
based on T₀−T₁≥the preset value A₁, and T₂−T₀<the preset value B₁, the compression refrigeration assembly is connected to the first heat exchange assembly, and the second heat exchange assembly is connected to the multi-way valve to form self-circulation;
based on T₂>T₁>T₀, a preset value A₃≤T₁−T₀<a preset value A₂, and T₂−T₀≥the preset value B₁, the first heat exchange assembly, the first dry cooler assembly and the compression refrigeration assembly are connected, and the second dry cooler assembly is connected to the second heat exchange assembly;
based on T₁−T₀<the preset value A₃, and T₂−T₀≥the preset value B₁, the first heat exchange assembly is connected to the compression refrigeration assembly, and the second dry cooler assembly is connected to the second heat exchange assembly;
based on T₁−T₀<the preset value A₃, and T₂−T₀≥the preset value B₁, the first heat exchange assembly performs the self-circulation via the multi-way valve, the second dry cooler assembly is connected to the second heat exchange assembly; or the second heat exchange assembly is connected to the multi-way valve to perform the self-circulation.

In some embodiments, the temperature of the first heat exchange assembly and the temperature of the second heat exchange assembly are acquired, the external ambient temperature is T₀; the temperature of the first heat exchange assembly is T₁; the temperature of the second heat exchange assembly is T₂; a temperature control assembly includes a compression refrigeration assembly, a first dry cooler assembly and a second dry cooler assembly; the first heat exchange assembly and the second heat exchange assembly are connected in series,
based on T₀>T₁ and T₀>T₂, the first heat exchange assembly, the second heat exchange assembly, and the compression refrigeration assembly are connected;
based on T₁>T₀, T₂>T₀, a preset value A₃≤T₁, and an average value of T₁ and T₂−T₀≤a preset value A₂, at least one of the first dry cooler assembly and the second dry cooler assembly, the compression refrigeration assembly, the first heat exchange assembly, and the second heat exchange assembly are connected in sequence;
based on T₁>T₀, T₂>T₀, and the average value of T₁ and T₂−T₀>the preset value A₂, at least one of the first dry cooler assembly and the second dry cooler assembly is connected to the first heat exchange assembly and the second heat exchange assembly in sequence.

In some embodiments, based on an average value of T₁ and T₃−T₀>a preset value A₃ (unit 1 and unit 2 do not need refrigeration), wherein the first heat exchange assembly and the second heat exchange assembly form a self-heating circulation loop.

The present disclosure provides in embodiments a liquid cooling system, including a first device to be temperature-controlled; a second device to be temperature-controlled; and the liquid cooling unit as described in any of the above embodiments, wherein the first heat exchange assembly is connected to the first device to be temperature-controlled, and the second heat exchange assembly is connected to the second device to be temperature-controlled.

### BRIEF DESCRIPTION OF THE DRAWINGS

FIG. 1 shows an arrangement diagram for a liquid cooling unit, including first and second refrigeration assemblies, and a multi-way valve within which a refrigerant flows in a first circulation pattern, according to an embodiment of the present disclosure.

FIG. 2 shows an arrangement diagram for a liquid cooling unit, including first and second refrigeration assemblies, and a multi-way valve within which a refrigerant flows in a second circulation pattern, according to an embodiment of the present disclosure.

FIG. 3 shows an arrangement diagram for a liquid cooling unit, including first and second refrigeration assemblies, and a multi-way valve within which a refrigerant flows in a third circulation pattern, according to an embodiment of the present disclosure.

FIG. 4 shows an arrangement diagram for a liquid cooling unit, including first and second refrigeration assemblies, and a multi-way valve within which a refrigerant flows in a fourth circulation pattern, according to an embodiment of the present disclosure.

FIG. 5 shows an arrangement diagram for a liquid cooling unit, including first and second refrigeration assemblies, and a multi-way valve within which a refrigerant flows in a fifth circulation pattern, according to an embodiment of the present disclosure.

FIG. 6 shows an arrangement diagram for a liquid cooling unit, including first, second and third refrigeration assemblies, and a multi-way valve within which a refrigerant flows in a first circulation pattern, according to another embodiment of the present disclosure.

FIG. 7 shows an arrangement diagram for a liquid cooling unit, including first, second and third refrigeration assemblies, and a multi-way valve within which a refrigerant flows in a second circulation pattern, according to another embodiment of the present disclosure.

FIG. 8 shows an arrangement diagram for a liquid cooling unit, including first, second and third refrigeration assemblies, and a multi-way valve within which a refrigerant flows in a third circulation pattern, according to another embodiment of the present disclosure.

FIG. 9 shows an arrangement diagram for a liquid cooling unit, including first, second and third refrigeration assemblies, and a multi-way valve within which a refrigerant flows in a fourth circulation pattern, according to another embodiment of the present disclosure.

FIG. 10 shows an arrangement diagram for a liquid cooling unit, including first, second and third refrigeration assemblies, and a multi-way valve within which a refrigerant flows in a fifth circulation pattern, according to another embodiment of the present disclosure.

FIG. 11 shows an arrangement diagram for a liquid cooling unit, including three refrigeration assemblies, a cut-off valve, and a multi-way valve within which a refrigerant flows in a first circulation pattern, according to still another embodiment of the present disclosure.

FIG. 12 shows an arrangement diagram for a liquid cooling unit, including three refrigeration assemblies, a cut-off valve, and a multi-way valve within which a refrigerant flows in a second circulation pattern, according to still another embodiment of the present disclosure.

FIG. 13 shows an arrangement diagram for a liquid cooling unit, including three refrigeration assemblies, a cut-off valve, and a multi-way valve within which a refrigerant flows in a third circulation pattern, according to still another embodiment of the present disclosure.

FIG. 14 shows an arrangement diagram for a liquid cooling unit, including three refrigeration assemblies, a cut-off valve, and a multi-way valve within which a refrigerant flows in a fourth circulation pattern, according to still another embodiment of the present disclosure.

FIG. 15 shows an arrangement diagram for a liquid cooling unit, including three refrigeration assemblies, a cut-off valve, and a multi-way valve within which a refrigerant flows in a fifth circulation pattern, according to still another embodiment of the present disclosure.

FIG. 16 shows an arrangement diagram for a liquid cooling unit, in which a compression refrigeration assembly and a second dry cooler assembly share a common fan; and a refrigerant flows in a first circulation pattern within a multi-way valve, according to still another embodiment of the present disclosure.

FIG. 17 shows an arrangement diagram for a liquid cooling unit, in which a compression refrigeration assembly and a second dry cooler assembly share a common fan; and a refrigerant flows in a second circulation pattern within a multi-way valve, according to still another embodiment of the present disclosure.

FIG. 18 shows an arrangement diagram for a liquid cooling unit, in which a compression refrigeration assembly and a second dry cooler assembly share a common fan; and a refrigerant flows in a third circulation pattern within a multi-way valve, according to still another embodiment of the present disclosure.

FIG. 19 shows an arrangement diagram for a liquid cooling unit, in which a compression refrigeration assembly and a second dry cooler assembly share a common fan; and a refrigerant flows in a fourth circulation pattern within a multi-way valve, according to still another embodiment of the present disclosure.

FIG. 20 shows an arrangement diagram for a liquid cooling unit, in which a compression refrigeration assembly and a second dry cooler assembly share a common fan; and a refrigerant flows in a fifth circulation pattern within a multi-way valve, according to still another embodiment of the present disclosure.

FIG. 21 shows an arrangement diagram for a liquid cooling unit, in which a refrigerant flows in a first circulation pattern within a multi-way valve including a first multi-way valve and a second multi-way valve, according to yet another embodiment of the present disclosure.

FIG. 22 shows an arrangement diagram for a liquid cooling unit, in which a refrigerant flows in a second circulation pattern within a multi-way valve including a first multi-way valve and a second multi-way valve, according to yet another embodiment of the present disclosure.

FIG. 23 shows an arrangement diagram for a liquid cooling unit, in which a refrigerant flows in a third circulation pattern within a multi-way valve including a first multi-way valve and a second multi-way valve, according to yet another embodiment of the present disclosure.

FIG. 24 shows an arrangement diagram for a liquid cooling unit, in which a refrigerant flows in a fourth circulation pattern within a multi-way valve including a first multi-way valve and a second multi-way valve, according to yet another embodiment of the present disclosure.

FIG. 25 shows an arrangement diagram for a liquid cooling unit, including a nine-way valve within which a refrigerant flows in a first circulation pattern, according to yet another embodiment of the present disclosure.

FIG. 26 shows an arrangement diagram for a liquid cooling unit, including a nine-way valve within which a refrigerant flows in a second circulation pattern, according to yet another embodiment of the present disclosure.

FIG. 27 shows an arrangement diagram for a liquid cooling unit, including a nine-way valve within which a refrigerant flows in a third circulation pattern, according to yet another embodiment of the present disclosure.

FIG. 28 shows an arrangement diagram for a liquid cooling unit, including a nine-way valve within which a refrigerant flows in a fourth circulation pattern, according to yet another embodiment of the present disclosure.

FIG. 29 shows an arrangement diagram for a liquid cooling unit, including a nine-way valve within which a refrigerant flows in a fifth circulation pattern, according to yet another embodiment of the present disclosure.

FIG. 30 shows an arrangement diagram for a liquid cooling unit, including a nine-way valve within which a refrigerant flows in a sixth circulation pattern, according to yet another embodiment of the present disclosure.

FIG. 31 shows an arrangement diagram for a liquid cooling unit, including a nine-way valve within which a refrigerant flows in a seventh circulation pattern, according to yet another embodiment of the present disclosure.

FIG. 32 shows an arrangement diagram for a liquid cooling unit, including a nine-way valve within which a refrigerant flows in an eighth circulation pattern, according to yet another embodiment of the present disclosure.

FIG. 33 shows an arrangement diagram for a liquid cooling unit, including a heat pump assembly, and a multi-way valve within which a refrigerant flows in a first circulation pattern, according to yet another embodiment of the present disclosure.

FIG. 34 shows an arrangement diagram for a liquid cooling unit, including a heat pump assembly, and a multi-way valve within which a refrigerant flows in a second circulation pattern, according to yet another embodiment of the present disclosure.

FIG. 35 shows an arrangement diagram for a liquid cooling unit, including a heat pump assembly, and a multi-way valve within which a refrigerant flows in a third circulation pattern, according to yet another embodiment of the present disclosure.

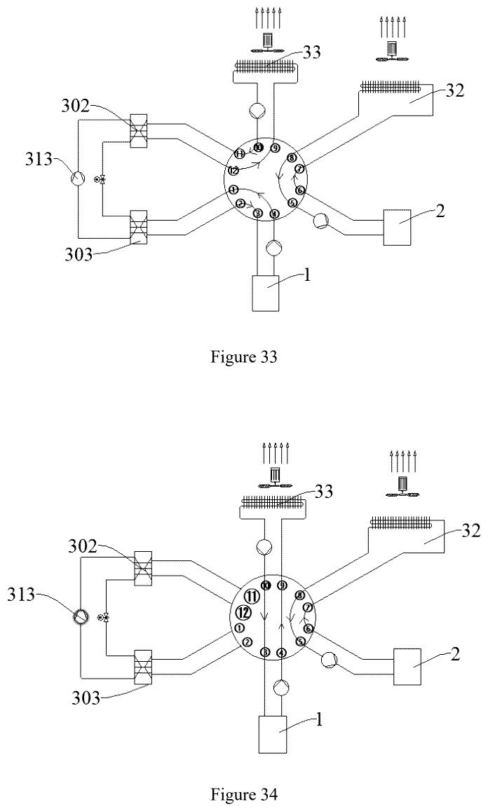

FIG. 33 shows an arrangement diagram for a liquid cooling unit, including a heat pump assembly, and a multi-way valve within which a refrigerant flows in a fourth circulation pattern, according to yet another embodiment of the present disclosure.

FIG. 37 shows an arrangement diagram for a liquid cooling unit, additionally including a condenser bypass assembly, and a multi-way valve within which a refrigerant flows in a first circulation pattern, according to yet another embodiment of the present disclosure.

### REFERENCE SIGNS

a first heat exchange assembly 1; a first heat exchange pipe 11; a first heat exchanger body 12; a first pump body 13;
a second heat exchange assembly 2; a second heat exchange pipe 21; a second heat exchanger body 22; a second pump body 23;
a compression refrigeration assembly 31; a condensation pipeline 311; a plate heat exchanger 312; a compressor 313; a first condenser 314; an expansion valve 315; a second condenser (a condensation end) 302; an evaporator (an evaporation end) 303;
a first dry cooler assembly 32; a first dry cooler liquid-inlet pipe 321; a first dry cooler body 322; a first dry cooler liquid-outlet pipe 323;
a second dry cooler assembly 33; a second dry cooler liquid-inlet pipe 331; a second dry cooler body 332; a second dry cooler liquid-outlet pipe 333;
a multi-way valve 4; a first multi-way valve 41; a second multi-way valve 42;
a first fan 51; a second fan 52;
a cut-off valve 6;
a condenser bypass pipeline 71; a second expansion valve 72; a dehumidifying evaporator 73; a dehumidifying fan 74.

### DETAILED DESCRIPTION

The following provides a detailed description of the embodiments of the present disclosure, which are illustrated in the accompanying drawings. The embodiments described below with reference to the accompanying drawings are exemplary and intended to explain the present disclosure, and should not be construed as limiting the present disclosure.

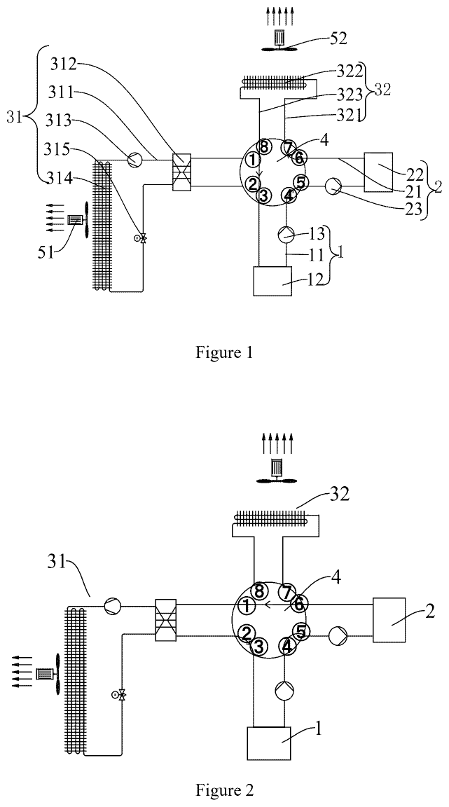

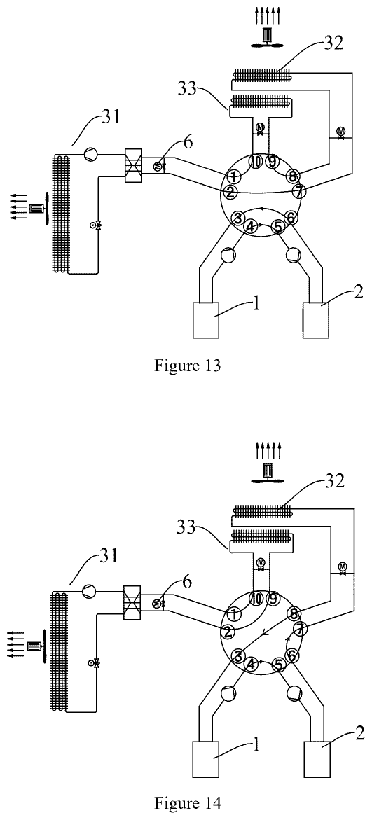

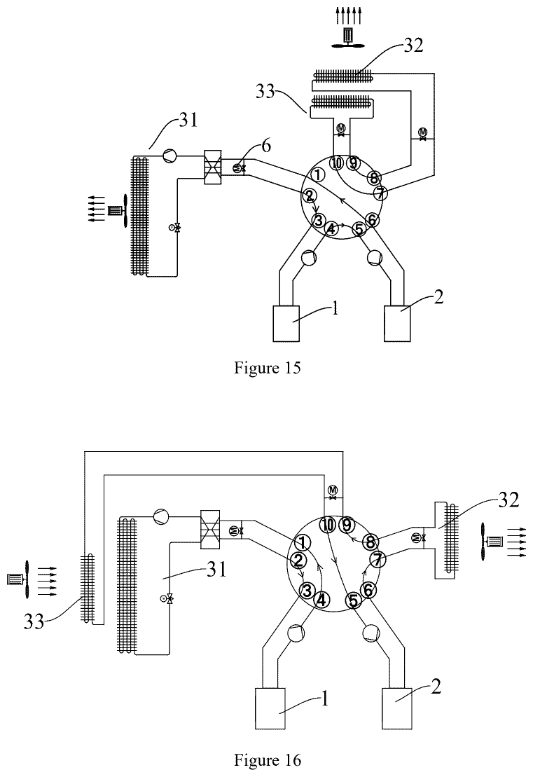

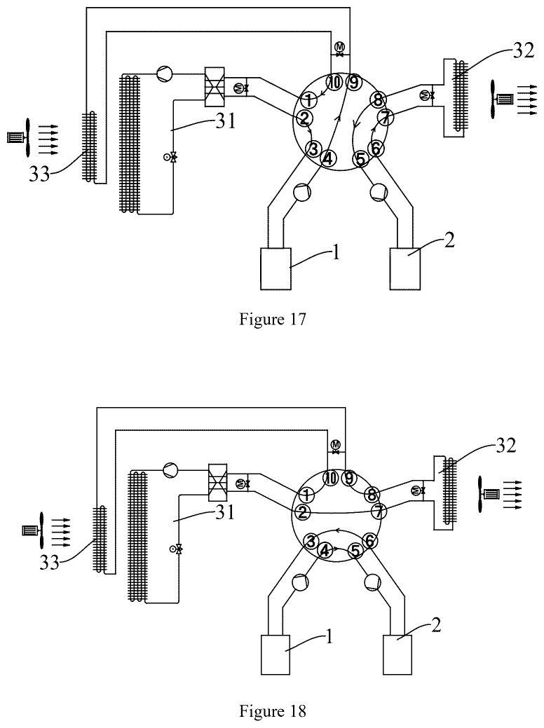

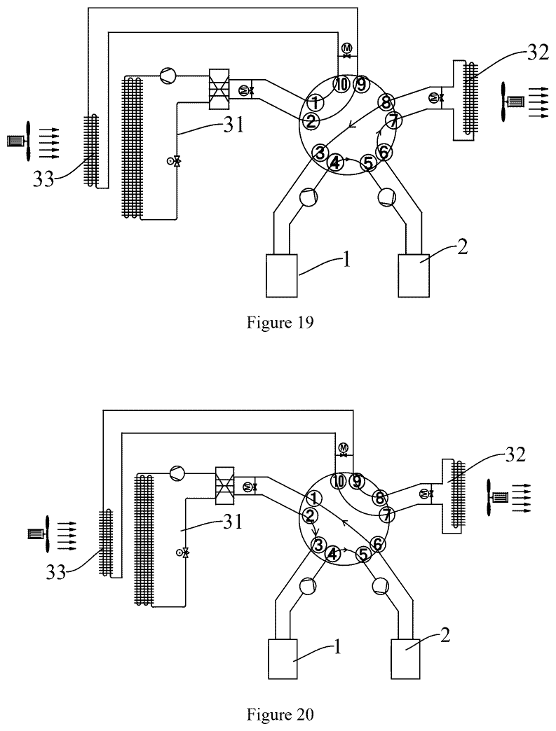

The liquid cooling unit of embodiments of the present disclosure is described below with reference to FIG. 1 to FIG. 37.

In embodiments of the present disclosure, the liquid cooling unit includes a first heat exchange assembly 1, a second heat exchange assembly 2, a temperature sensor, a temperature control assembly, and a multi-way valve 4.

The first heat exchange assembly 1 is configured to heat exchange with a first device to be temperature-controlled; the second heat exchange assembly 2 is configured to heat exchange with a second device to be temperature-controlled. The first heat exchange assembly 1, the second heat exchange assembly 2 and the temperature control assembly each are connected to the multi-way valve 4, to achieve conversion between multiple operation modes by means of a corresponding parameter of the temperature sensor and switching of the multi-way valve 4. It would be understood that the liquid cooling unit is configured to switch between multiple operation modes.

The liquid cooling unit in this embodiment of the present disclosure switches between multiple operation modes via the multi-way valve 4, depending on practical operation conditions, thus enhancing energy efficiency of the liquid cooling unit with an advantage of energy saving.

Besides, it is possible to simplify arrangement of pipeline to a certain extend by conversion via the multi-way valve 4, thus facilitating installation and maintenance of the liquid cooling unit.

Thus, the liquid cooling unit provided in embodiments of the present disclosure is advantageous in reduced energy consumption and convenient installation and maintenance.

In some embodiments, the first device to be temperature-controlled may be a battery, and the second device to be temperature-controlled may be an inverter.

The application of the present disclosure is not limited to this, in other embodiments, the first device to be temperature-controlled may include multiple separate units to be temperature-controlled, which are in different demands of temperature control. Accordingly, the second device to be temperature-controlled may also include multiple separate units to be temperature-controlled, which are in different demands of temperature control. In practical application, the multiple units to be temperature-controlled are in different demands of temperature control. For example, the multiple units to be temperature-controlled may be connected in parallel.

As shown in FIG. 1 to FIG. 5, the temperature control assembly includes a first refrigeration assembly and a second refrigeration assembly.

The liquid cooling unit is provided with a first operation mode, a second operation mode, and a third operation mode; and the liquid cooling unit is configured to switch between the first operation mode, the second operation mode, and the third operation mode via the multiple-way valve 4.

In the first operation mode, the first heat exchange assembly 1 is connected to the second heat exchange assembly 2 in series, to form series connected heat exchange elements. The first heat exchange assembly 1 and the second heat exchange assembly 2 are connected to at least one of the second refrigeration assembly and the first refrigeration assembly via the multiple-way valve 4 to form a refrigeration loop.

In the second operation mode, the first refrigeration assembly is capable of connecting to the first heat exchange assembly 1 via some ports of the multi-way valve 4 to form a first loop; the second refrigeration assembly is capable of connecting to the second heat exchange assembly 2 via other ports of the multi-way valve 4 to form a second loop.

In the third operation mode, the first heat exchange assembly 1 and the second heat exchange assembly 2 form a self-heating circulation loop.

The liquid cooling unit in this embodiment of the present disclosure, by switching between the first operation mode, the second operation mode, and the third operation mode, allows for conversion between series connection and parallel connection, achieving different operation modes for the liquid cooling unit under different operation conditions, improving utilization of natural cooling, thereby enhancing energy efficiency of the liquid cooling unit. Meanwhile, it is possible to switch to another heat exchange unit when some heat exchange unit fails, achieving safety backup.

For example, the temperature control assembly includes a first refrigeration assembly and a second refrigeration assembly. The first refrigeration assembly is the compression refrigeration assembly 31; the second refrigeration assembly is the first dry cooler assembly 32; the multi-way valve 4 is an eight-way valve, which is provided with a first port, a second port, a third port, a fourth port, a fifth port, a sixth port, a seventh port, and an eighth port.

In the first operation mode, the first heat exchange assembly 1 is connected to the second heat exchange assembly 2 in series; and the first heat exchange assembly 1 and the second heat exchange assembly 2 are connected to at least one of the second refrigeration assembly and the first refrigeration assembly via the multiple-way valve 4 to form a refrigeration loop.

For example, as shown in FIG. 1, the first heat exchange assembly 1 and the second heat exchange assembly 2 are connected in series and form a circulation loop with the first dry cooler assembly 32. In specific, the liquid outlet of the first heat exchange assembly 1, the fourth port, the fifth port, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the third port, and the liquid inlet of the first heat exchange assembly 1 form a circulation liquid channel. Such a circulation pattern of a refrigerant is applicable to where the ambient temperature is lower than the required inlet and outlet liquid temperatures of the first heat exchange assembly 1 and the second heat exchange assembly 2, and the heat-exchange capacity of the first dry cooler assembly 32 meets the total heat demand of the first heat exchange assembly 1 and the second heat exchange assembly 2. Accordingly, it can perform refrigeration by only activating the first dry cooler assembly 32, with an advantage of further saving energy consumption.

For example, as shown in FIG. 2, the first heat exchange assembly 1 and the second heat exchange assembly 2 are connected in series and form a circulation loop with the compression refrigeration assembly 31. In specific, the liquid outlet of the first heat exchange assembly 1, the fourth port, the fifth port, the liquid inlet of the second heat exchange assembly 2, the liquid outlet of the second heat exchange assembly 2, the sixth port, the first port, the liquid inlet of the compression refrigeration assembly 31, the liquid outlet of the compression refrigeration assembly 31, the second port, the third port, and the liquid inlet of the first heat exchange assembly 1 form a circulation liquid channel.

Such a circulation pattern of a refrigerant in the liquid cooling unit in this embodiment of the present disclosure is advantageous in strong capability for temperature control, and serves as a safety backup solution to switch when the first dry cooler assembly 32 fails.

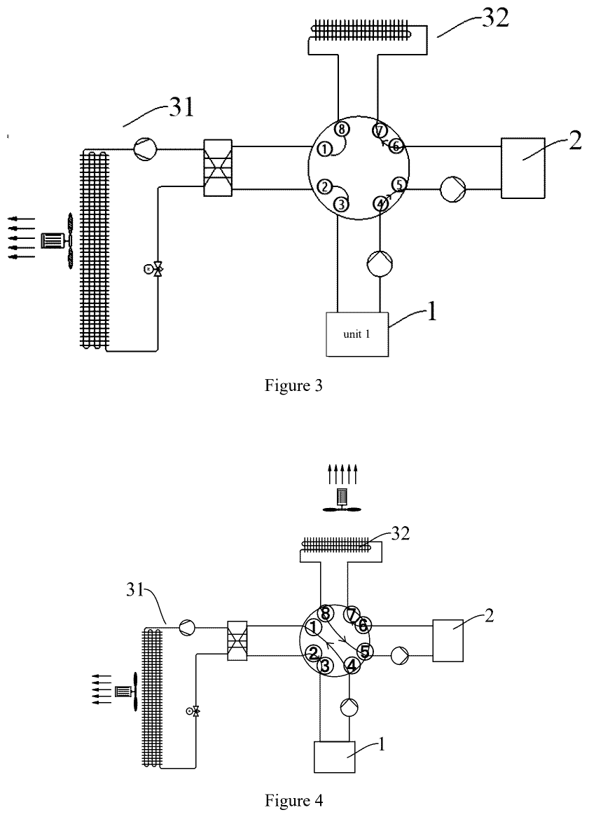

For example, as shown in FIG. 3, the first heat exchange assembly 1 and the second heat exchange assembly 2 are connected in series and form a circulation loop with the first dry cooler assembly 32 and the compression refrigeration assembly 31. In specific, the liquid outlet of the first heat exchange assembly 1, the fourth port, the fifth port, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the first port, the liquid inlet of the compression refrigeration assembly 31, the liquid outlet of the compression refrigeration assembly 31, the second port, the third port, and the liquid inlet of the first heat exchange assembly 1 form a circulation liquid channel.

Such a circulation pattern of a refrigerant in the liquid cooling unit in this embodiment of the present disclosure is applicable to where the ambient temperature is lower than the required inlet and outlet liquid temperatures of the first heat exchange assembly 1 and the second heat exchange assembly 2, and the heat-exchange capacity of the dry cooler does not meet the total heat demand of the first heat exchange assembly 1 and the second heat exchange assembly 2. With the compression refrigeration assembly and the first dry cooler assembly 32 connected in series, the liquid cooling unit is advantageous in increased cooling rate. Accordingly, such an operation mode may be activated when the first heat exchange assembly 1 and the second heat exchange assembly 2 require rapid cooling.

Further, it is possible to switch between the respective circulation loops as shown in FIG. 1, FIG. 2, and FIG. 3 via the multi-way valve 4.

The liquid cooling unit in this embodiment of the present disclosure, by switching between the respective circulation loops as shown in FIG. 1, FIG. 2, and FIG. 3 via the multi-way valve 4, achieves conversion between different operation modes under different operation conditions, improving utilization of natural cooling, and thereby enhancing energy efficacy of the liquid cooling unit.

In the second operation mode, the first heat exchange assembly 1 and the second heat exchange assembly 2 are not connected, in other words, the first heat exchange assembly 1 forms a self-circulation with the multi-way valve 4, or the first heat exchange assembly 1 forms a cooling channel with at least one of the compression refrigeration assembly 31 and the first dry cooler assembly 32; and the second heat exchange assembly 2 forms a self-circulation with the multi-way valve 4, or the second heat exchange assembly 2 forms another cooling channel with at least another of the compression refrigeration assembly 31 and the first dry cooler assembly 32.

According to the liquid cooling unit in this embodiment of the present disclosure, the compression refrigeration assembly 31, the first heat exchange assembly 1 and the multi-way valve 4 form a first loop; and the first dry cooler assembly 32, the second heat exchange assembly 2 and the multi-way valve 4 form a second loop. These two loops are applicable to where the first heat exchange assembly 1 and the second heat exchange assembly 2 are in different demands of temperature control, specifically to where the required inlet and outlet liquid temperatures of the second heat exchange assembly 2 are higher than the ambient temperature, and the required inlet and outlet liquid temperatures of the first heat exchange component 1 are lower than the ambient temperature. The system where two heat exchange assemblies are connected in parallel facilitates separate operations for the two heat exchange assemblies, one for compression refrigeration and the other one for natural cooling under the ambient temperature, thus facilitating to reduction of the load on the compressor 313 in the compression refrigeration assembly 31, maximizing utilization of natural cooling, and improving energy efficiency of the liquid cooling unit.

For example, as shown in FIG. 4, the compression refrigeration assembly 31, the first heat exchange assembly 1 and the multi-way valve 4 form a first loop; while the first dry cooler assembly 32, the second heat exchange assembly 2 and the multi-way valve 4 form a second loop.

In specific, the liquid outlet of the first heat exchange assembly 1, the fourth port, the first port, the liquid inlet of the compression refrigeration assembly 31, the liquid outlet of the compression refrigeration assembly 31, the second port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation channel.

In the third operation mode, the first heat exchange assembly 1 and the second heat exchange assembly 2 form a self-heating circulation loop.

The liquid cooling unit in this embodiment of the present disclosure, by the first heat exchange assembly 1 and the second heat exchange assembly 2 forming a self-heating circulation loop, is applicable to where the first heat exchange assembly 1 and the second heat exchange assembly 2 do not need refrigeration, such as shutdown insulation; or to where the first heat exchange assembly 1 and the second heat exchange assembly 2 need to balance respective temperatures. Heat generated by a certain component (e.g., a water pump) in the first heat exchange assembly 1 may be utilized to heat or maintain the water temperature. Besides, use of two heat exchange assemblies to form a self-heating circulation loop balances respective temperatures of the two systems, or use of the higher temperature system to heat the lower temperature system. Therefore, the liquid cooling unit is advantageous in further reducing energy consumption.

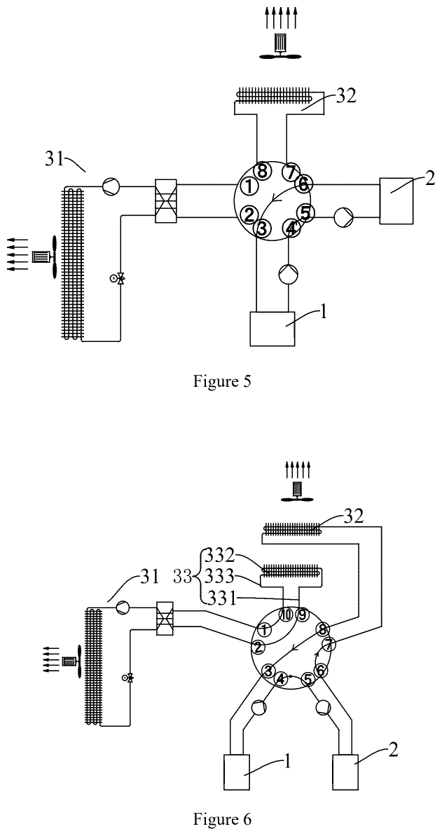

In specific, for example, as shown in FIG. 5, the liquid outlet of the first heat exchange assembly 1, the fourth port, the fifth port, the liquid inlet of the second heat exchange assembly 2, the liquid outlet of the second heat exchange assembly 2, the sixth port, the third port, and the liquid inlet of the first heat exchange assembly 1 form a circulation liquid channel.

As shown in FIG. 6 to FIG. 24, the temperature control assembly includes a first refrigeration assembly, a second refrigeration assembly, and a third refrigeration assembly. In the first operation mode, the series connected heat exchange elements are connected to at least one of the second refrigeration assembly, the first refrigeration assembly, and the third refrigeration assembly via the multi-way valve 4 to form a refrigeration loop. In specific, the first refrigeration assembly is the compression refrigeration assembly 31, the second refrigeration assembly is the first dry cooler assembly 32, the third refrigeration assembly is the second dry cooler assembly 33, the multi-way valve 4 is a ten-way valve, which is provided with a first port, a second port, a third port, a fourth port, a fifth port, a sixth port, a seventh port, an eighth port, a ninth port, and the tenth port.

The liquid cooling unit in embodiments of the present disclosure, by arranging three refrigeration assemblies, further expands types of the operation modes, and further improves the matching degree between practical operation conditions and refrigeration effects. Besides, it also maximizes a heat exchange area of the refrigeration assembly, thus increasing refrigeration capacity and enhancing energy efficiency.

In some embodiments, the circulating medium in the first dry cooler assembly 32 and the second dry cooler assembly 33 is a 50% ethylene glycol aqueous solution.

For example, the first heat exchange assembly 1 and the second heat exchange assembly 2 are connected in series to form series connected heat exchange elements, which are connected to one of the dry coolers.

In specific, as shown in FIG. 6, the first heat exchange assembly 1 and the second heat exchange assembly 2 are connected in series and form a circulation loop with the first dry cooler assembly 32. The liquid outlet of the first heat exchange assembly 1, the fourth port, the fifth port, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the third port, and the liquid inlet of the first heat exchange assembly 1 form a circulation liquid channel.

The liquid cooling unit in embodiments of the present disclosure, the first heat exchange assembly 1 and the second heat exchange assembly 2 are connected in series and form a circulation loop with the first dry cooler assembly 32, applicable to where the ambient temperature is lower than the required inlet and outlet liquid temperatures of the first heat exchange assembly 1 and the second heat exchange assembly 2, and the heat-exchange capacity of the first dry cooler assembly 32 or the second dry cooler assembly 33 meets the total heat demand of the first heat exchange assembly 1 and the second heat exchange assembly 2. Accordingly, use of the dry cooler for refrigeration is advantageous in low energy consumption.

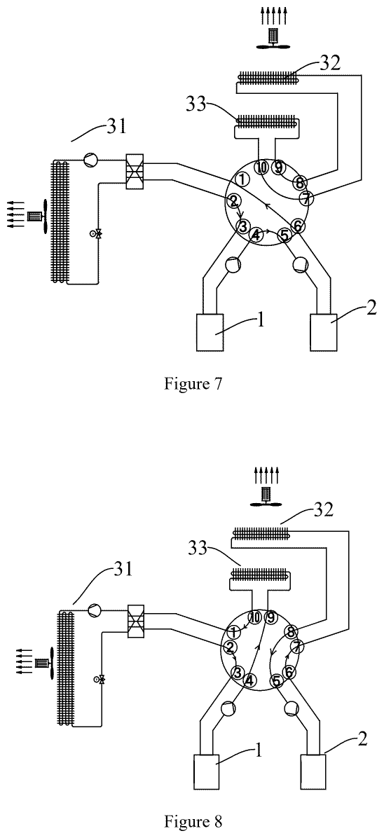

For example, as shown in FIG. 7, the first heat exchange assembly 1 and the second heat exchange assembly 2 are connected in series and form a circulation loop with the compression refrigeration assembly 31. In specific, the liquid outlet of the first heat exchange assembly 1, the fourth port, the fifth port, the liquid inlet of the second heat exchange assembly 2, the liquid outlet of the second heat exchange assembly 2, the sixth port, the first port, the liquid inlet of the compression refrigeration assembly 31, the liquid outlet of the compression refrigeration assembly 31, the second port, the third port and the liquid inlet of the first heat exchange assembly 1 form a circulation liquid channel.

Further, conversion between respective circulation patterns of a refrigerant as shown in FIG. 6 and FIG. 7 can be achieved via the multi-way valve 4. According to the liquid cooling unit in embodiments of the present disclosure, the first heat exchange assembly 1 and the second heat exchange assembly 2 are connected in series and form a circulation loop with the compression refrigeration assembly 31, meanwhile it is switchable between series connection with the dry cooler and series connection with the compression refrigeration, thus improving loop safety, where it is possible to switch to another mode when any loop fails.

Series connected heat exchange elements (i.e., series connected first heat exchange assembly 1 and second heat exchange assembly 2) may also form a circulation loop with the second dry cooler assembly 33. The series connected heat exchange elements may form a circulation loop with the first dry cooler assembly 32 and the compression refrigeration assembly 31. The series connected heat exchange elements may also form a circulation loop with the second dry cooler assembly 33 and the compression refrigeration assembly 31. The series connected heat exchange elements may also form a circulation loop with the first dry cooler assembly 32, the second dry cooler assembly 33, and the compression refrigeration assembly 31.

In the first operation mode, the series connected heat exchange elements form respective multiple refrigeration loops with at least one of the second refrigeration assembly, the first refrigeration assembly, the third refrigeration assembly, where the multiple refrigeration loops are switchable via the multi-way valve 4.

As shown in FIG. 6 to FIG. 36, the temperature control assembly includes a first refrigeration assembly, a second refrigeration assembly, and a third refrigeration assembly; where the first refrigeration assembly is the compression refrigeration assembly 31, the second refrigeration assembly is the first dry cooler assembly 32, and the third refrigeration assembly is the second dry cooler assembly 33; in the second operation mode, the first refrigeration assembly and the third refrigeration assembly are connected to the first heat exchange assembly 1 via the multi-way valve 4 in sequence to form a third loop; and the second refrigeration assembly is connected to the second heat exchange assembly 2 via the multi-way valve 4 in sequence to form a fourth loop.

In specific, the first refrigeration assembly is the compression refrigeration assembly 31, the second refrigeration assembly is the first dry cooler assembly 32, and the third refrigeration assembly is the second dry cooler assembly 33; in the second operation mode, the compression refrigeration assembly 31 and the second dry cooler assembly 33 are connected to the first heat exchange assembly 1 via the multi-way valve 4 in sequence to form a third loop; and the first dry cooler assembly 32 is connected to the second heat exchange assembly 2 via the multi-way valve 4 in sequence to form a fourth loop.

For example, as shown in FIG. 8, the liquid outlet of the first heat exchange assembly 1, the fourth port, the ninth port, the liquid inlet of the second dry cooler assembly 33, the liquid outlet of the second dry cooler assembly 33, the tenth port, the first port, the liquid inlet of the compression refrigeration assembly 31, the liquid outlet of the compression refrigeration assembly 31, the second port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, the liquid inlet of the second heat exchange assembly 2 form a circulation liquid channel.

The liquid cooling unit in this embodiment of the present disclosure is applied to where the ambient temperature is lower than the required inlet and outlet liquid temperatures of the first heat exchange assembly 1 and the second heat exchange assembly 2, and the heat-exchange capacity of the first dry cooler assembly 32 meets the heat-exchange demand of the second heat exchange assembly 2. Accordingly, use of the first dry cooler assembly 32 alone for refrigeration to the second heat exchange assembly 2 is advantageous in low energy consumption as compared to combined refrigeration with the compression refrigeration assembly 31. Besides, the liquid cooling unit in embodiments of the present disclosure, by arranging a refrigerant out of the first heat exchange assembly 1 to pass through the second dry cooler assembly 33 for cooling first and enter the compression refrigeration assembly 31 subsequently, reducing the load on the compressor 313, thus further reducing the energy consumption of the liquid cooling unit.

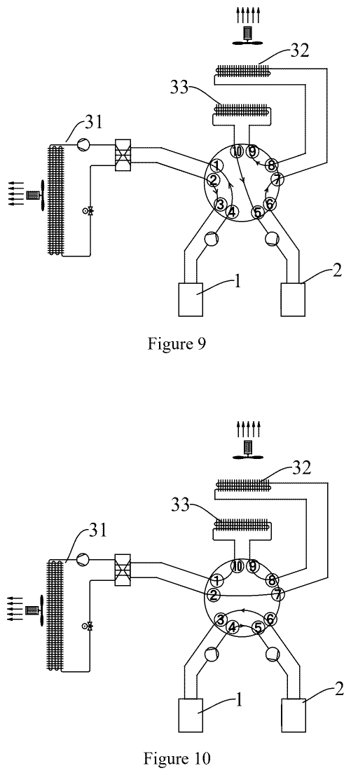

For example, as shown in FIG. 9, the liquid outlet of the first heat exchange assembly 1, the forth port, the first port, the liquid inlet of the compression refrigeration assembly 31, the liquid outlet of the compression refrigeration assembly 31, the second port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of first dry cooler assembly 32, the eighth port, the ninth port, the liquid inlet of the second dry cooler assembly 33, the liquid outlet of the second dry cooler assembly 33, the tenth port, the fifth port, and the liquid inlet of the second heat exchange assembly 2 form a circulation liquid channel.

In the third operation mode, the first heat exchange assembly 1 and the second heat exchange assembly 2 form a self-heating circulation loop.

In specific, for example, as shown in FIG. 10, the liquid outlet of the first heat exchange assembly 1, the fourth port, the fifth port, the liquid inlet of the second heat exchange assembly 2, the liquid outlet of the second heat exchange assembly 2, the sixth port, the third port, and the liquid inlet of the first heat exchange assembly 1 form a circulation liquid channel.

In the second operation mode, the multi-way valve 4 includes a first multi-way valve 41 and a second multi-way valve 42; one liquid outlet of the first multi-way valve 41 is connected to the liquid inlet of the first refrigeration assembly via a joint pipe, and the second multi-way valve 42 is arrange at the joint pipe, so that at least one of the first refrigeration assembly and the third refrigeration assembly is connected to the first heat exchange assembly 1 in sequence to form respective parallel loops by switching the second multi-way valve 42.

The liquid cooling unit in embodiments of the present disclosure, by arranging the first multi-way valve 41 and the second multi-way valve 42, simplifies the structure of the multi-way valve 4, and simplifies the structure of the flow channel in the multi-way valve 4, thus reducing leakage risk and enhancing feasibility.

For example, the multi-way valve 4 includes a first multi-way valve 41 and a second multi-way valve 42; the first multi-way valve 41 is provided with a first port, a second port, a third port, a fourth port, a fifth port, a sixth port, a seventh port, and an eighth port; the second multi-way valve 42 is a three-way valve, which is provided with a first liquid-inlet port, a first liquid outlet and a second liquid outlet; the first port is connected to the liquid inlet of the first refrigeration assembly via a joint pipe; the second multi-way valve 42 is arranged at the joint pipe; the first liquid-inlet port is connected to the first port; the first liquid outlet is connected to the liquid inlet of the third refrigeration assembly; the second liquid outlet is connected to the liquid inlet of the first refrigeration assembly, so that at least one of the first refrigeration assembly and the third refrigeration assembly is connected to the first heat exchange assembly 1 by switching-on/off each of the first liquid-inlet port, the first liquid outlet and the second liquid outlet.

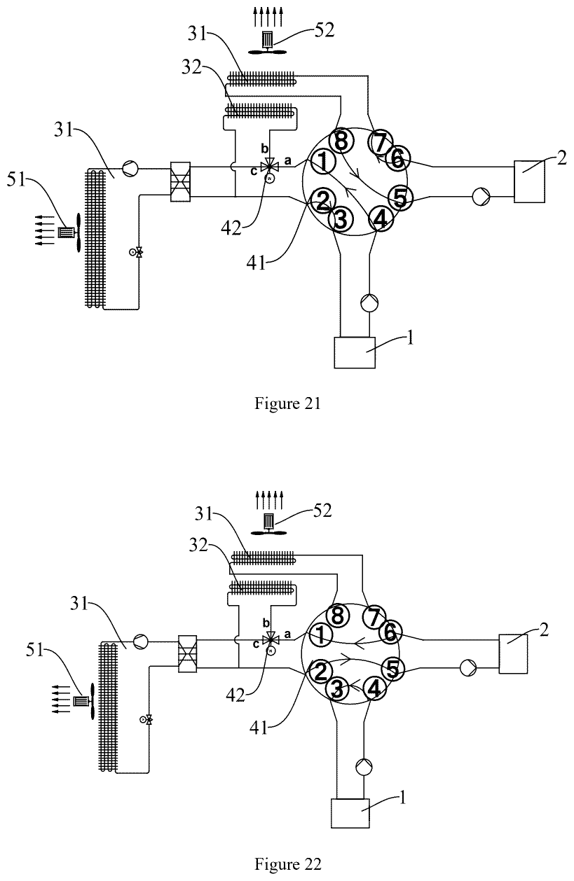

In specific, in the second operation mode, the liquid outlet of the first heat exchange assembly 1, the fourth port, the first port, the first liquid-inlet port, the first liquid outlet (e.g., the port “b” as shown in FIG. 21 to FIG. 24), and/the second liquid outlet (e.g., the port “c” as shown in FIG. 21 to FIG. 24), . . . , in sequence form three different loops, which may be achieved by switching on/off the three-way valve, with an advantage of convenient conversion.

For example, as shown in FIG. 21, the liquid outlet of the first heat exchange assembly 1, the fourth port, the first port, the first liquid-inlet port, the first liquid outlet (e.g., the port “b” as shown in FIG. 21 to FIG. 24), the liquid inlet of the second dry cooler assembly 33, the liquid outlet of the second dry cooler assembly 33, the second port, the third port, the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

The liquid cooling unit in this embodiment of the present disclosure is applicable to where the ambient temperature is lower than the required inlet and outlet liquid temperatures of the second heat exchange assembly 2. The first heat exchange assembly 1 employs the compression refrigeration assembly 31 or the second dry cooler assembly 33 for cooling, while the second heat exchange assembly 2 employs the first dry cooler assembly 32 for cooling. The two heat exchange units operate separately, with an advantage of further enhanced energy efficacy.

In specific, in the second operation mode, the liquid outlet of the second heat exchange assembly 2, the sixth port, the first port, the first liquid-inlet port, the first liquid outlet (e.g., the port “b” as shown in FIG. 21 to FIG. 24), and/the second liquid outlet (e.g., the port “c” as shown in FIG. 21 to FIG. 24), . . . , in sequence form three different loops, which are achieved by switching on/off the three-way valve, with an advantage of convenient conversion.

For example, as shown in FIG. 22, the liquid outlet of the second heat exchange assembly 2, the sixth port, the first port, the first liquid-inlet port, the first liquid outlet (e.g., the port “b” as shown in FIG. 21 to FIG. 24), the liquid inlet of the second dry cooler assembly 33, the liquid outlet of the second dry cooler assembly 33, the second port, the fifth port, and the liquid inlet of the second heat exchange assembly 2 form a circulation liquid channel; while the liquid outlet of the first heat exchange assembly 1, the fourth port, the third port, and the liquid inlet of the first heat exchange assembly 1 form a self-circulation loop.

The liquid cooling unit in this embodiment of the present disclosure is applicable to where the first heat exchange assembly 1 does not need refrigeration, while the second heat exchange assembly 2 employs the second dry cooler assembly 33 or the compression refrigeration assembly 31 for compression refrigeration, serving as an emergence measurement when the first dry cooler assembly 32 fails, thereby enhancing reliability of the liquid cooling unit.

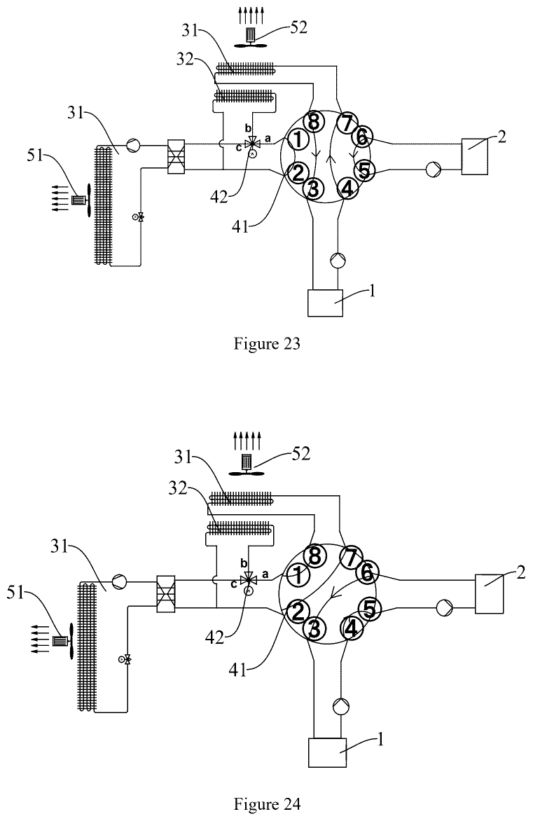

In some embodiments, as shown in FIG. 23, the liquid outlet of the first heat exchange assembly 1, the fourth port, the seventh port, the liquid inlet of the first dry cooler assembly 32, the liquid outlet of the first dry cooler assembly 32, the eighth port, the third port, and the liquid inlet of the first heat exchange assembly 1 form a circulation liquid channel; while the liquid outlet of the second heat exchange assembly 2, the sixth port, the fifth port, the liquid inlet of the second heat exchange assembly 2 form a self-circulation loop.

The liquid cooling unit in this embodiment of the present disclosure is applicable to where the second heat exchange assembly 2 does not need refrigeration, while the first heat exchange assembly 1 employs the first dry cooler assembly 32 for cooling, which is applied to where the ambient temperature is lower than the required inlet and outlet liquid temperatures of the first heat exchange assembly 1, serving as an emergence measurement when the second dry cooler assembly 33 or the compression refrigeration assembly 31 fails, thereby enhancing reliability of the liquid cooling unit.

In the third operation mode, the first heat exchange assembly 1 and the second heat exchange assembly 2 form a self-heating circulation loop.

In specific, for example, as shown in FIG. 24, the liquid outlet of the first heat exchange assembly 1, the fourth port, the fifth port, the liquid inlet of the second heat exchange assembly 2, the liquid outlet of the second heat exchange assembly 2, the sixth port, the third port, and the liquid inlet of the first heat exchange assembly 1 form a circulation liquid channel.

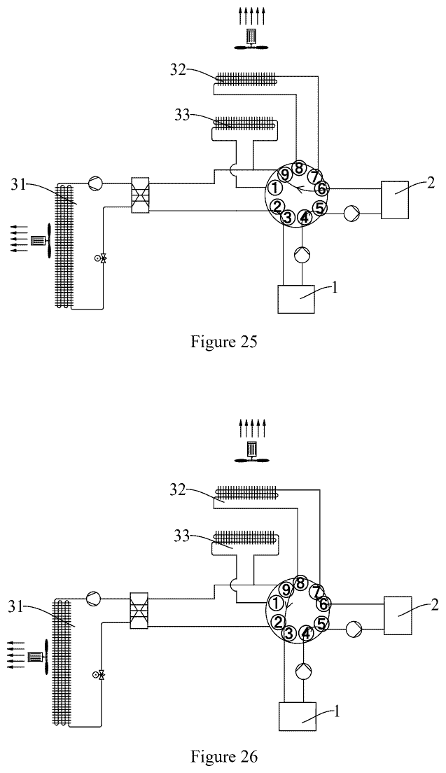

The present disclosure is not limited to this, as shown in FIG. 25 to FIG. 32, the temperature control assembly includes a first refrigeration assembly, a second refrigeration assembly, and a third refrigeration assembly; in the first operation mode, the series connected heat exchange elements are connected to at least one of the second refrigeration assembly, the first refrigeration assembly, the third refrigeration assembly via the multi-way valve 4 to form a refrigeration loop. In specific, the first refrigeration assembly is the compression refrigeration assembly 31; the second refrigeration assembly is the first dry cooler assembly 32; the third refrigeration assembly is the second dry cooler assembly 33; the multi-way valve 4 is a nine-way valve, which is provided with a first port, a second port, a third port, a fourth port, a fifth port, a sixth port, a seventh port, an eighth port, and a ninth port; the liquid inlet of the compression refrigeration assembly 31 and the liquid inlet of the second dry cooler assembly 33 share the ninth port; the liquid outlet of the compression refrigeration assembly 31 is connected to the second port; the liquid outlet of the second dry cooler assembly 33 is connected to the first port. In addition, the first dry cooler assembly 32 and the second dry cooler assembly 33 share a first fan; a condenser of the compression refrigeration assembly 31 is arranged opposite to a second fan; and the circulating medium in the first dry cooler assembly 32 and the second dry cooler assembly 33 is a 50% ethylene glycol aqueous solution.

In the first operation mode, for example, the first heat exchange assembly 1 and the second heat exchange assembly 2 are connected in series to form series connected heat exchange elements, which are connected to one dry cooler.

As shown in FIG. 25, the first heat exchange assembly 1 and the second heat exchange assembly 2 are connected in series and form a circulation loop with the compression refrigeration assembly 31. In specific, the liquid outlet of the first heat exchange assembly 1, the fourth port, the fifth port, the liquid inlet of the second heat exchange assembly 2, the liquid outlet of the second heat exchange assembly 2, the sixth port, ninth port, the liquid inlet of the compression refrigeration assembly 31, the liquid outlet of the compression refrigeration assembly 31, the second port, the third port, and the liquid inlet of the first heat exchange assembly 1 are in communication.

The liquid cooling unit in this embodiment of the present disclosure employs a nine-way valve to achieve switching between multiple operation modes, simplifies pipeline connection between two valves as compared to the structure of an eight-way valve plus a three-way valve, allowing for a more compact space. Such an arrangement provides higher tightness as compared to the ten-way valve due to one less port, thus enhancing reliability.

As shown in FIG. 26, the first heat exchange assembly 1 and the second heat exchange assembly 2 are connected in series and form a circulation loop with the first dry cooler assembly 32. In specific, the liquid outlet of the first heat exchange assembly 1, the fourth port, the fifth port, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the third port, and the liquid inlet of the first heat exchange assembly 1 are in communication.

The liquid cooling unit in this embodiment of the present disclosure is applied to where the ambient temperature is lower than the required inlet and outlet liquid temperatures of the first heat exchange assembly 1 and the second heat exchange assembly 2, and the heat-exchange capacity of the first dry cooler assembly 32 meets the total heat-exchange demand of the firs heat exchange assembly 1 and the second heat exchange assembly 2. Use of the first dry cooler assembly 32 alone facilitates to enhancing the energy efficacy of the liquid cooling unit, and improving safety and reliability, serving as backup when the second dry cooler assembly 33 and the compression refrigeration assembly 31 fails.

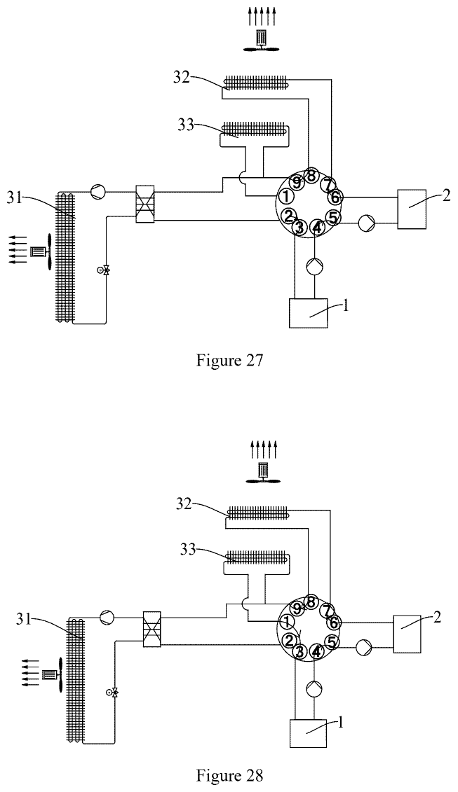

As shown in FIG. 27, the first heat exchange assembly 1 and the second heat exchange assembly 2 are connected in series and form a circulation loop with the first dry cooler assembly 32 and the compression refrigeration assembly 31. In specific, the liquid outlet of the first heat exchange assembly 1, the fourth port, the fifth port, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the ninth port, the liquid inlet of the compression refrigeration assembly 31, the liquid outlet of the compression refrigeration assembly 31, the second port, the third port, and the liquid inlet of the first heat exchange assembly 1 are in communication.

The liquid cooling unit in this embodiment of the present disclosure is applied to where the ambient temperature is lower than the required inlet and outlet liquid temperatures of the first heat exchange assembly 1 and the second heat exchange assembly 2, and the heat-exchange capacity of the first dry cooler assembly 32 is lower than the total heat-exchange demand of the first heat exchange assembly 1 and the second heat exchange assembly 2, thus it is necessary to arrange the compression refrigeration assembly 31 (plate exchange) to follow the first dry cooler assembly 32, thereby reducing the load on the compressor 313 and improving the energy efficiency of the liquid cooling unit.

As shown in FIG. 28, the first heat exchange assembly 1 and the second heat exchange assembly 2 are connected in series and form a circulation loop with the first dry cooler assembly 32 and the second dry cooler assembly 33. In specific, the liquid outlet of the first heat exchange assembly 1, the fourth valve, the fifth valve, the liquid inlet of the second heat exchange assembly 2, the liquid outlet of the second heat exchange assembly 2, the sixth port, the seventh port, the liquid inlet of the first dry cooler assembly 32, the liquid outlet of the first dry cooler assembly 32, the eighth port, the ninth port, and the liquid inlet of the second dry cooler assembly 33, the liquid outlet of the second dry cooler assembly 33, the first port, the third port, and the liquid inlet of the first heat exchange assembly 1 are in communication.

The liquid cooling unit in this embodiment of the present disclosure is applied to where the ambient temperature is lower than the required inlet and outlet liquid temperatures of the first heat exchange assembly 1 and the second heat exchange assembly 2, and the heat-exchange capacity of the first dry cooler assembly 32 and the second dry cooler assembly 33 meets the total heat-exchange demand of the first second heat exchange assembly 2. Use of the first dry cooler assembly 32 and the second dry cooler assembly 33 for cooling avoids from activating the compressor 313, thus enhancing the energy efficiency of the liquid cooling unit.

In the second operation mode, the first heat exchange assembly 1 and the second heat exchange assembly 2 are not connected, in other words, the first heat exchange assembly 1 forms a self-circulation with the multi-way valve 4, or the first heat exchange assembly 1 forms a cooling channel with at least one of the compression refrigeration assembly 31 and the first dry cooler assembly 32; and the second heat exchange assembly 2 forms a self-circulation with the multi-way valve 4, or the second heat exchange assembly 2 forms another cooling channel with at least one of the compression refrigeration assembly 31 and the first dry cooler assembly 32.

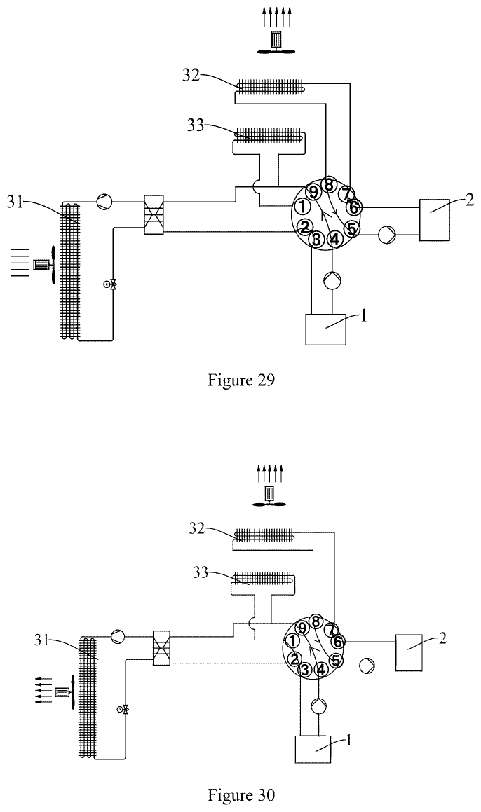

For example, as shown in FIG. 29, the compression refrigeration assembly 31, the first heat exchange assembly 1 and the multi-way valve 4 form a first loop; while the first dry cooler assembly 32, the second heat exchange assembly 2 and the multi-way valve 4 form a second loop.

The liquid cooling unit in this embodiment of the present disclosure is applied to where the ambient temperature is higher than the required inlet and outlet liquid temperatures of the first heat exchange assembly 1, and lower than the required inlet and outlet liquid temperatures of the second heat exchange assembly 2. The first heat exchange assembly 1 employs compression refrigeration; while the second heat exchange assembly 2 employs a dry cooler for cooling. Such an arrangement includes two separate loops from each other, enhancing the energy efficiency of the liquid cooling unit without mutual interference between two loops.

In specific, the liquid outlet of the first heat exchange assembly 1, the fourth port, the ninth port, the liquid inlet of the compression refrigeration assembly 31, the liquid outlet of the compression refrigeration assembly 31, the second port, the third port, and the liquid inlet of the heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

For example, as shown in FIG. 30, the second dry cooler assembly 33, the first heat exchange assembly 1 and the multi-way valve 4 form a first loop; while the first dry cooler assembly 32, the second heat exchange assembly 2 and the multi-way valve 4 form a second loop.

The liquid cooling unit in this embodiment of the present disclosure is applied to where the ambient temperature is lower than the required inlet and outlet liquid temperatures of the first heat exchange assembly 1 or the second heat exchange assembly 2, the heat-exchange capacity of the first dry cooler assembly 32 meets the heat-exchange demand of the second heat exchange assembly 2, the heat-exchange capacity of the second dry cooler assembly 33 meets the heat-exchange demand of the first heat exchange assembly 1, enhancing energy efficiency of the liquid cooling unit without mutual interference between two separate loops.

In specific, the liquid outlet of the first heat exchange assembly 1, the fourth port, the ninth port, the liquid inlet of the second dry cooler assembly 33, the liquid outlet of the second dry cooler assembly 33, the first port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, the liquid inlet of the second heat exchange assembly 2 form a circulation liquid channel.

For example, as shown in FIG. 32, the first heat exchange assembly 1 and the multi-way valve 4 form a self-circulation loop; while the first dry cooler assembly 32, the second heat exchange assembly 2, and the multi-way valve 4 form a first loop. In specific, the liquid outlet of the first heat exchange assembly 1, the fourth port, the third port, and the liquid inlet of the first heat exchange assembly 1 form the self-circulation loop; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

In the third operation mode, the first heat exchange assembly 1 and the second heat exchange assembly 2 form a self-heating circulation loop.

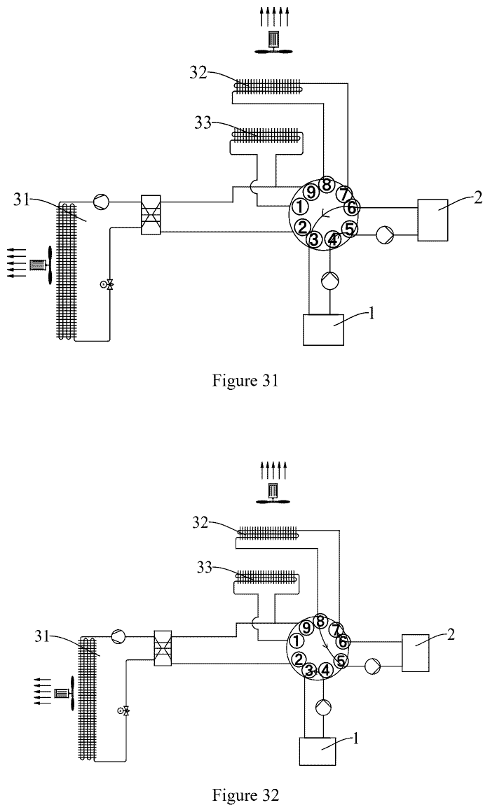

In specific, for example, as shown in FIG. 31, the liquid outlet of the first heat exchange assembly 1, the fourth port, the fifth port, the liquid inlet of the second heat exchange assembly 2, the liquid outlet of the second heat exchange assembly 2, the sixth port, the third port, and the liquid inlet of the first heat exchange assembly 1 form a circulation liquid channel.

The liquid cooling unit in this embodiment of the present disclosure is applied or applicable to where no refrigeration is required, such as shutdown insulation; or to where the first heat exchange assembly 1 and the second heat exchange assembly 2 need to balance respective temperatures. Heat generated by a water pump may be utilized to heat or maintain the water temperature, with an advantage of reduced energy consumption.

The liquid cooling unit is further provided with a fourth operation mode, the temperature control assembly further includes a heater; wherein in the fourth operation mode, the heater is connected to the first heat exchange assembly 1 and/or the second heat exchange assembly 2 via the multi-way valve 4 to achieve heating of a corresponding device to be temperature-controlled, so that the liquid cooling unit is allowed to switch between the first operation mode, the second operation mode, the third operation mode, and the fourth operation mode.

The liquid cooling unit in this embodiment of the present disclosure, by being arranged to operate in the fourth operation mode, further expands its application scenario.

The temperature control assembly includes a heat pump assembly, wherein the heat pump assembly includes (a second condenser 302) a condensation end and (an evaporator 303) an evaporation end, wherein the condensation end and the evaporation end each are connected to respective ports of the multi-way valve 4, wherein the condensation end is connected to the first heat exchange assembly 1 and/or the second heat exchange assembly 2 via the multi-way valve 4 to form a heat pump heating loop. In other words, the condensation end is connected to the first heat exchange assembly 1 via the multi-way valve 4 to form a first heat pump heating loop; the condensation end is connected to the second heat exchange assembly 2 via the multi-way valve 4 to form a second heat pump heating loop; the condensation end is connected to the first heat exchange assembly 1 and the second heat exchange assembly 2 via the multi-way valve 4 to form a third heat pump heating loop. It would be understood that the first refrigeration assembly and the heater are integrated to form the heat pump assembly. This design has the advantages of small space occupation and low energy consumption.

The liquid cooling unit in this embodiment of the present disclosure, by use of heat pump heating, is more energy-saving and energy-efficient as compared to traditional electric heating.

In some embodiments, switching between the first heat pump heating loop, the second heat pump heating loop, and the third heat pump heating loop are achieved by switching the core of the multi-way valve 4.

In some embodiments, the evaporation end is connected to the first heat exchange assembly 1 and/or the second heat exchange assembly 2 via the multi-way valve 4 to form a heat pump refrigeration loop, wherein the heat pump heating loop and the heat pump refrigeration loop are switchable to each other.

In some embodiments, the heat pump assembly includes a heat pump circulation pipeline, a condensation end, an evaporation end, a compressor 313, and a third expansion valve, wherein the condensation end, the evaporation end, the compressor 313, and the third expansion valve are arranged at the heat pump circulation pipeline in sequence.

In some embodiments, for example, as shown in FIG. 33 to FIG. 36, the first refrigeration assembly includes the evaporation end of the heat pump assembly; the second refrigeration assembly is a first dry cooler assembly 32; the third refrigeration assembly is a second dry cooler assembly 33; and the heater is the condensation end of the heat pump assembly. The evaporation end and the condensation end of the heat pump assembly are switchable communicated to the multi-way valve 4. The multi-way valve 4 is a twelve-way valve, which is provided with a first port, a second port, a third port, a fourth port, a fifth port, a sixth port, a seventh port, an eighth port, a ninth port, a tenth port, an eleventh port, and a twelfth port.

In the first operation mode, the differences from the above embodiments are the use of the evaporation end of the heat pump assembly instead of the compression refrigeration assembly 31; and a pipeline corresponding to the condensation end is connected to the eleventh port and the twelfth port. In the first operation mode, the pipeline corresponding to the condensation end is connected to the eleventh port and the twelfth port without communication with the core of the multi-way valve 4. For example, the first heat exchange assembly 1 and the second heat exchange assembly 2 are connected in series and form a circulation loop with the evaporation end of the heat pump assembly. Alternatively, the first heat exchange assembly 1 and the second heat exchange assembly 2 are connected in series and form a circulation loop with the first dry cooler assembly 32. Alternatively, the first heat exchange assembly 1 and the second heat exchange assembly 2 are connected in series and form a circulation loop with the second dry cooler assembly 33.

In the second operation mode, for example, as shown in FIG. 33, the liquid outlet of the first heat exchange assembly 1, the fourth port, the first port, the liquid inlet of the evaporation end of the heat pump assembly, the liquid outlet of the evaporation end of the heat pump assembly, the second port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

In the second operation mode, as shown in FIG. 34, for example, the first heat exchange assembly 1 and the second dry cooler assembly 33 are connected; and the second heat exchange assembly 2 is connected to the first dry cooler assembly 32. In specific, the liquid outlet of the first heat exchange assembly 1, the fourth port, the ninth port, the liquid inlet of the second dry cooler assembly 33, the liquid outlet of the second dry cooler assembly 33, the tenth port, the third port, and the liquid inlet of the first heat exchange assembly 1 form a circulation liquid channel; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

In the third operation mode, the first heat exchange assembly 1 and the second heat exchange assembly 2 form a self-heating circulation loop.

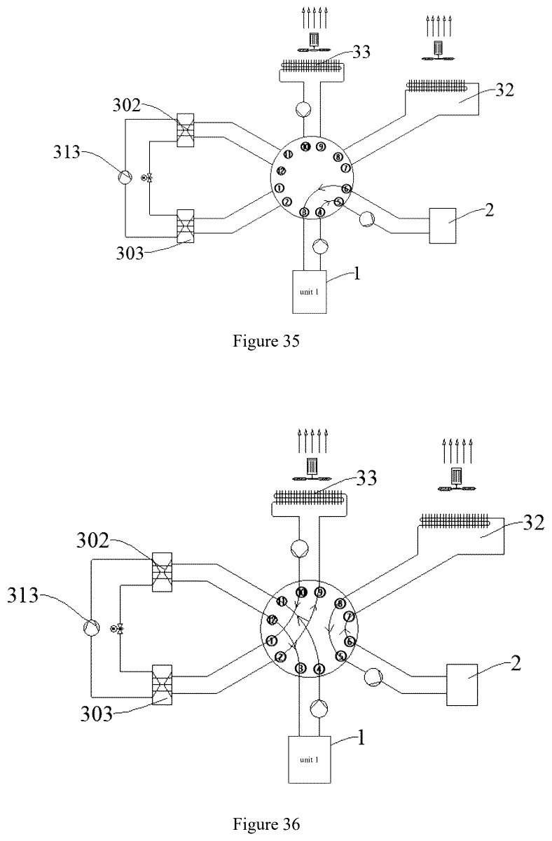

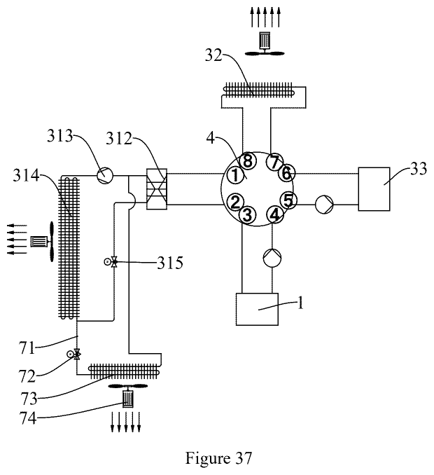

In specific, for example, as shown in FIG. 35, the liquid outlet of the first heat exchange assembly 1, the fourth port, the fifth port, the liquid inlet of the second heat exchange assembly 2, the liquid outlet of the second heat exchange assembly 2, the sixth port, the third port, and the liquid inlet of the first heat exchange assembly 1 form a circulation liquid channel.

In the fourth operation mode, for example, as shown in FIG. 36, the liquid outlet of the first heat exchange assembly 1, the fourth port, the eleventh port, the liquid inlet of the condensation end of the heat pump assembly, the liquid outlet of the condensation end of the heat pump assembly, the twelfth port, the third port, and the liquid inlet of the first heat exchange assembly 1 form a heat pump heating loop; while the liquid outlet of the second heat exchange assembly 2, the sixth port, the seventh port, the liquid inlet of the first dry cooler assembly 32, the liquid outlet of the first dry cooler assembly 32, the eighth port, the fifth port, and the liquid inlet of the second heat exchange assembly 2 form a circulation liquid channel.

In some embodiments, for example as shown in FIG. 1 to FIG. 32, the compression refrigeration assembly 31 includes a condensation pipeline 311, a plate heat exchange 312, a compressor 313, a first condenser 314, a first expansion valve 315, and a first heat exchange pipeline; wherein the plate heat exchanger 312, the compressor 313, the first condenser 314, and the first expansion valve 315 are sequentially arranged at the condensation pipeline 311 in a direction along which a condensation gas flows in the condensation pipeline 311 and form a refrigeration circulation loop correspondingly; and the first heat exchange pipeline is connected to the plate heat exchanger 312 and the multi-way valve 4 to form a heat dissipation circulation loop.

In some embodiments, the first dry cooler assembly 32 includes a first dry cooler liquid-inlet pipe 321, a first dry cooler body 322, and a first dry cooler liquid-outlet pipe 323; a liquid inlet of the first dry cooler liquid-inlet pipe 321 is connected to a liquid outlet of the multi-way valve 4; a liquid outlet of the first dry cooler liquid-inlet pipe 321 is connected to a liquid inlet of the first dry cooler body 322; a liquid outlet of the first dry cooler body 322 is connected to a liquid inlet of the first dry cooler liquid-outlet pipe 323; and a liquid outlet of the first dry cooler liquid-outlet pipe 323 is connected to a liquid inlet of the multi-way valve 4.

In some embodiments, the second dry cooler assembly 33 includes a second dry cooler liquid-inlet pipe 331, a second dry cooler body 332, and a second dry cooler liquid-outlet pipe 333; a liquid inlet of the second dry cooler liquid-inlet pipe 331 is connected to a liquid outlet of the multi-way valve 4; a liquid outlet of the second dry cooler liquid-inlet pipe 331 is connected to a liquid inlet of the second dry cooler body 332; a liquid outlet of the second dry cooler body 332 is connected to a liquid inlet of the second dry cooler liquid-outlet pipe 333; and a liquid outlet of the second dry cooler liquid-outlet pipe 333 is connected to a liquid inlet of the multi-way valve 4.

In some embodiments, the liquid cooling unit further includes a condenser bypass assembly connected to the temperature control assembly.

In some embodiments, as shown in FIG. 37, the condenser bypass assembly includes a condenser bypass pipeline 71, a second expansion valve 72, a dehumidifying evaporator 73, and a dehumidifying fan 74; the second expansion valve 72 and the dehumidifying evaporator 73 are arranged at the condenser bypass pipeline 71; an air inlet of the condenser bypass pipeline 71 is arranged at a pipeline between the condenser and the first expansion valve 315; and the dehumidifying fan 74 is arranged opposite to the dehumidifying evaporator 73.

According to the liquid cooling unit in this embodiment of the present disclosure, when dehumidification is required due to higher environmental humidity, the refrigeration system dehumidifies a box where the liquid cooling unit is placed to avoid the safety hazard of condensation occurring in an electronic component that causes electrical short circuit. Meanwhile, the arrangement of a condenser bypass can dehumidify the temperature control assembly (such as the condenser pipeline). Thus, it has the advantage of energy conservation.

In some embodiments, the liquid cooling unit further includes a first fan 51, wherein the first fan is arranged to correspond to respective evaporators of the first refrigeration assembly, the second refrigeration assembly, and the third refrigeration assembly. In other words, respective evaporators of the first refrigeration assembly, the second refrigeration assembly, and the third refrigeration assembly share the common first fan 51. With the common fan in combination of the refrigerant flows which of the first refrigeration assembly, the second refrigeration assembly, and the third refrigeration assembly first, it guarantees the function of the dry cooler or the condenser, and avoids large wind resistance caused by multiple series connected first fan 51.

The present disclosure is not limited to the above embodiment, the liquid cooling unit further includes a first fan 51 and a second fan 52, wherein the first fan 51 is arranged to correspond to one of respective evaporators of the first refrigeration assembly, the second refrigeration assembly, and the third refrigeration assembly; while the second fan 52 is arranged to correspond to other two of respective evaporators of the first refrigeration assembly, the second refrigeration assembly and the third refrigeration assembly.

For example, as shown in FIG. 6 to FIG. 15, the first fan 51 is arranged to correspond to the evaporator of the first refrigeration assembly; and the second fan 52 is arranged to correspond to each of respective evaporators of the second refrigeration assembly and the third refrigeration assembly.

Alternatively, for example, as shown in FIG. 16 to FIG. 20, the first fan 51 is arranged to correspond to each of respective evaporators of the first refrigeration assembly and the third refrigeration assembly; while the second fan 52 is arranged to correspond to the evaporator of the second refrigeration assembly.

The present disclosure is not limited to the above embodiment, the liquid cooling unit further includes a first fan 51, a second fan 52, and a third fan, which are arranged to correspond to the first refrigeration assembly, the second refrigeration assembly, and the third refrigeration assembly in one-to-one correspondence.

In specific, the first fan 51 is arranged to correspond to the evaporator of the first refrigeration assembly; the second fan 52 is arranged to correspond to the evaporator of the second refrigeration assembly; and the third fan is arranged to correspond to the evaporator of the third refrigeration assembly.

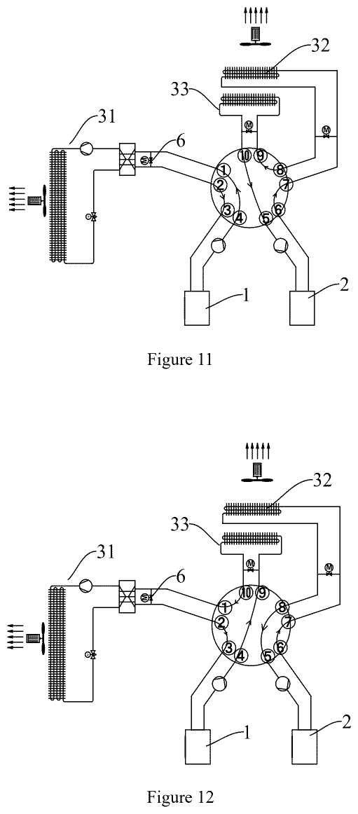

In some embodiments, for example, as shown in FIG. 11 to FIG. 20, a cut-off valve 6 is arranged between at least one of the compression refrigeration assembly 31, the first dry cooler assembly 32, and the second dry cooler assembly 33, and the multi-way valve 4.

The liquid cooling unit in this embodiment of the present disclosure, by arranging a cut-off valve 6, allows for short-circuiting the first dry cooler assembly 32 or the second dry cooler assembly 33, thus reducing flow resistance and power consumption of the water pump.

It would be understood that, in some embodiments, a cut-off valve 6 is arranged between at least one of the compression refrigeration assembly 31, the first dry cooler assembly 32, and the second dry cooler assembly 33, and the multi-way valve 4.

The present disclosure is not limited to the above embodiment, in some other embodiments, a cut-off valve 6 is arranged between two of the compression refrigeration assembly 31, the first dry cooler assembly 32, and the second dry cooler assembly 33, and the multi-way valve 4.

The present disclosure is not limited to the above embodiment, in some other embodiments, a cut-off valve 6 is arranged between each of the compression refrigeration assembly 31, the first dry cooler assembly 32, and the second dry cooler assembly 33, and the multi-way valve 4.

For example, as shown in FIG. 11 to FIG. 20, the first refrigeration assembly is the compression refrigeration assembly 31, the second refrigeration assembly is the first dry cooler assembly 32, and the third refrigeration assembly is the second dry cooler assembly 33. The cut-off valve 6 includes a first cut-off valve, a second cut-off valve, and a third cut-off valve. The first cut-off valve is arrange at a pipeline of the compression refrigeration assembly 31; the second cut-off valve is arrange at a pipeline of the first dry cooler assembly 32; and the third cut-off valve is arrange at a pipeline of the second dry cooler assembly 33.

The first heat exchange assembly 1 includes a first heat exchange pipe 11, a first heat exchanger body 12, and a first pump body 13; both the first heat exchanger body 12 and the first pump body 13 are arranged at the first heat exchange pipe 11; and the first heat exchange pipe 11 is circularly connected to the multi-way valve 4. The second heat exchange assembly 2 includes a second heat exchange pipe 21, a second heat exchanger body 22, and a second pump body 23; both the second heat exchanger body 22 and the second pump body 23 are arranged at the second heat exchange pipe 21; and the second heat exchange pipe 21 is circularly connected to the multi-way valve 4.

The present disclosure provides in embodiments a method for controlling a liquid cooling unit, the method including: acquiring an external ambient temperature; acquiring a temperature of the first heat exchange assembly 1 and/or a temperature of the second heat exchange assembly 2; and switching operation modes via a multi-way valve 4. Accordingly, the method for controlling a liquid cooling unit in this embodiment of the present disclosure, by switching between multiple operation modes via the multi-way valve 4, switches depending on practical operation conditions, enhancing the energy efficiency of the liquid cooling unit. Therefore, it is advantageous in energy saving. Switching via the multi-way valve 4 simplifies the arrangement of the pipeline to a certain extent, facilitating to the installation and maintenance.

In some embodiments, the temperature of the first heat exchange assembly 1, the temperature of the second heat exchange assembly 2, and the ambient temperature are acquired.

The external ambient temperature is T₀; the temperature of the first heat exchange assembly 1 is T₁; the temperature of the second heat exchange assembly 2 is T₂. The temperature control assembly includes the compression refrigeration assembly 31, the first dry cooler assembly 32, and the second dry cooler assembly 33. The first refrigeration assembly is the compression refrigeration assembly 31; the second refrigeration assembly is the first dry cooler assembly 32, and the third refrigeration assembly is the second dry cooler assembly 33. In this embodiment, by arranging a temperature sensor in each of the first heat exchange assembly 1 and the second heat exchange assembly 2, respective temperatures thereof are collected.

Based on T₀−T₁≥a preset value A₁, and T₂−T₀≥a preset value B₁, the compression refrigeration assembly 31 is connected to the first heat exchange assembly 1, and at least one of the first dry cooler assembly 32 and the second dry cooler assembly 33 is connected to the second heat exchange assembly 2.

Based on T₀−T₁≥the preset value A₁, and T₂−T₀<the preset value B₁, the compression refrigeration assembly 31 is connected to the first heat exchange assembly 1, and the second heat exchange assembly 2 is connected to the multi-way valve 4 to form self-circulation.

Based on T₂>T₁>T₀, a preset value A₃≤T₁−T₀<a preset value A₂, and T₂−T₀≥the preset value B₁, the first heat exchange assembly 1, the first dry cooler assembly 32 and the compression refrigeration assembly 31 are connected, and the second dry cooler assembly 33 is connected to the second heat exchange assembly 2.

Based on T₁−T₀<the preset value A₃, and T₂−T₀≥the preset value B₁, the first heat exchange assembly 1 is connected to the compression refrigeration assembly 31, and the second dry cooler assembly 33 is connected to the second heat exchange assembly 2.

Based on T₁−T₀<the preset value A₃, and T₂−T₀≥the preset value B₁, the first heat exchange assembly 1 performs the self-circulation via the multi-way valve 4, the second dry cooler assembly 33 is connected to the second heat exchange assembly 2; or the second heat exchange assembly 2 is connected to the multi-way valve 4 to perform the self-circulation.

In some other embodiments, the temperature of the first heat exchange assembly 1 and the temperature of the second heat exchange assembly 2 are acquired; the external ambient temperature is T₀; the temperature of the first heat exchange assembly 1 is T₁; the temperature of the second heat exchange assembly 2 is T₂. The temperature control assembly includes the compression refrigeration assembly 31, the first dry cooler assembly 32 and the second dry cooler assembly 33; and the first heat exchange assembly 1 and the second heat exchange assembly 2 are connected in series.

Based on T₀>T₁ and T₀>T₂, the first heat exchange assembly 1, the second heat exchange assembly 2, and the compression refrigeration assembly 31 are connected.

Based on T₁>T₀, T₂>T₀, a preset value A₃≤T₁, and an average value of T₁ and T₂−T₀≤a preset value A₂, at least one of the first dry cooler assembly 32 and the second dry cooler assembly 33, the compression refrigeration assembly 31, the first heat exchange assembly 1, and the second heat exchange assembly 2 are connected in sequence.

Based on T₁>T₀, T₂>T₀, and the average value of T₁ and T₂−T₀>the preset value A₂, at least one of the first dry cooler assembly 32 and the second dry cooler assembly 33 is connected to the first heat exchange assembly 1 and the second heat exchange assembly 2 in sequence.

In some other embodiments, based on an average value of T₁ and T₃−T₀>a preset value A₃, wherein the first heat exchange assembly 1 and the second heat exchange assembly 2 form a self-heating circulation loop. Accordingly, it is applicable to where no refrigeration is required for the first heat exchange assembly 1 and the second heat exchange assembly 2, with the advantage of the energy consumption greatly saved.

The present disclosure provides in embodiments a liquid cooling system, including a first device to be temperature-controlled; a second device to be temperature-controlled; and the liquid cooling unit as described in any of the above embodiments, wherein the first heat exchange assembly 1 is connected to the first device to be temperature-controlled, and the second heat exchange assembly 2 is connected to the second device to be temperature-controlled. Accordingly, the liquid cooling system in embodiments of the present disclosure, by switching between multiple operation modes via the multi-way valve 4, switches depending on practical operation conditions, enhancing the energy efficiency of the liquid cooling unit. Therefore, it is advantageous in energy saving. Switching via the multi-way valve 4 simplifies the arrangement of the pipeline to a certain extent, facilitating to the installation and maintenance.

In the specification, it should be understood that, the terms indicating orientation or position relationship such as “central”, “longitudinal”, “lateral”, “width”, “thickness”, “above”, “below”, “front”, “rear”, “right”, “left”, “vertical”, “horizontal”, “top”, “bottom”, “inner”, “outer”, “clockwise”, “counter-clockwise”, “axial”, “radial”, “circumferential” should be construed to refer to the orientation or position relationship as described or as shown in the drawings. These terms are merely for convenience and concision of description and do not alone indicate or imply that the device or element referred to must have a particular orientation or must be configured or operated in a particular orientation. Thus, it cannot be understood to limit the present disclosure.

In addition, terms such as “first” and “second” are used herein for purposes of description and are not intended to indicate or imply relative importance or significance or impliedly indicate quantity of the technical feature referred to. Thus, the feature defined with “first” and “second” may comprise one or more this feature. In the description of the present disclosure, “multiple” means two or more, for example two and three, unless specified otherwise.

In the present disclosure, unless specified or limited otherwise, the terms “mounted”, “connected”, “coupled”, “fixed” and the like are used broadly, and may be, for example, fixed connections, detachable connections, or integrated connections; may also be mechanical or electrical connections or communications; may also be direct connections or indirect connections via intervening structures; may also be inner communications of two elements or mutual interaction between two elements, which can be understood by those skilled in the art according to specific situations.

In the present disclosure, unless specified or limited otherwise, a structure in which a first feature is “on” or “below” a second feature may be an embodiment in which the first feature is in direct contact with the second feature, or an embodiment in which the first feature and the second feature are contacted indirectly via an intermediation. Furthermore, a first feature “on”, “above” or “on top of” a second feature may include an embodiment in which the first feature is right or obliquely “on”, “above” or “on top of” the second feature, or just means that the first feature is at a height higher than that of the second feature; while a first feature “below”, “under” or “on bottom of” a second feature may be an embodiment in which the first feature is right or obliquely “below”, “under” or “on bottom of” the second feature, or just means that the first feature is at a height lower than that of the second feature.

Reference throughout this specification to “an embodiment”, “some embodiments”, “one embodiment”, “another example”, “an example”, “a specific example” or “some examples” means that a particular feature, structure, material, or characteristic described in connection with the embodiment or example is included in at least one embodiment or example of the present disclosure. Thus, the appearances of the phrases such as “in some embodiments”, “in one embodiment”, “in an embodiment”, “in another example”, “in an example”, “in a specific example” or “in some examples”, in various places throughout this specification are not necessarily referring to the same embodiment or example of the present disclosure. Furthermore, the particular features, structures, materials, or characteristics may be combined in any suitable manner in one or more embodiments or examples. In addition, skilled in the art can combine the different embodiments or examples described in this specification, as well as the features in different embodiments or examples, without conflicting with each other.

Although explanatory embodiments have been shown and described, it would be appreciated by those skilled in the art that the above embodiments cannot be construed to limit the present disclosure, and changes, alternatives, and modifications can be made in the embodiments in the scope of the present disclosure.

1. A liquid cooling unit, comprising:
a first heat exchange assembly, configured to heat exchange with a first device to be temperature-controlled;
a second heat exchange assembly, configured to heat exchange with a second device to be temperature-controlled;
a temperature control assembly; and
a multi-way valve,
wherein the first heat exchange assembly, the second heat exchange assembly and the temperature control assembly each are connected to the multi-way valve, to achieve conversion between multiple operation modes by switching of the multi-way valve.

2. The liquid cooling unit according to claim 1, wherein the temperature control assembly comprises a first refrigeration assembly and a second refrigeration assembly;
wherein the liquid cooling unit is provided with a first operation mode, a second operation mode, and a third operation mode; and the liquid cooling unit is configured to switch between the first operation mode, the second operation mode, and the third operation mode via the multiple-way valve, wherein
in the first operation mode, the first heat exchange assembly is connected to the second heat exchange assembly in series, at least one of the second refrigeration assembly and the first refrigeration assembly is connected to the first heat exchange assembly and the second heat exchange assembly via the multiple-way valve to form a refrigeration loop;
in the second operation mode, the first refrigeration assembly is connected to the first heat exchange assembly via some ports of the multi-way valve to form a first loop, and/or the second refrigeration assembly is connected to the second heat exchange assembly via other ports of the multi-way valve to form a second loop;
in the third operation mode, the first heat exchange assembly and the second heat exchange assembly form a self-heating circulation loop.

3. The liquid cooling unit according to claim 2, wherein the temperature control assembly further comprises a third refrigeration assembly;
in the first operation mode, at least one of the second refrigeration assembly, the first refrigeration assembly and the third refrigeration assembly is connected to the first heat exchange assembly and the second heat exchange assembly to form a refrigeration loop.

4. The liquid cooling unit according to claim 2, wherein the temperature control assembly further comprises a third refrigeration assembly;
in the second operation mode, the first refrigeration assembly and the third refrigeration assembly are connected to the first heat exchange assembly via the multi-way valve in sequence to form a third loop, and the second refrigeration assembly is connected to the second heat exchange assembly via the multi-way valve in sequence to form a fourth loop; or
wherein the first refrigeration assembly is connected to the first heat exchange assembly via the multi-way valve in sequence to form a fifth loop, and
the second refrigeration assembly and the third refrigeration assembly are connected to the second heat exchange assembly via the multi-way valve in sequence to form a sixth loop.

5. (canceled)

6. The liquid cooling unit according to claim 3, wherein at least one of the second refrigeration assembly, the first refrigeration assembly and the third refrigeration assembly is connected to the first heat exchange assembly and the second heat exchange assembly to form multiple refrigeration loops, which are switchable via the multi-way valve.

7. The liquid cooling unit according to claim 4, wherein the first loop and the second loop are switchable to the third loop and the fourth loop via the multi-way valve; or the first loop and the second loop are switchable to the fifth loop and the sixth loop via the multi-way valve.

8. The liquid cooling unit according to claim 7, wherein the third loop and the fourth loop form a first loop set; the fifth loop and the sixth loop form a second loop set; and the first loop set and the second loop set are switchable to each other via a core of the multi-way valve.

9. The liquid cooling unit according to claim 3, wherein the multi-way valve comprises a house and a core arranged inside the house; the house is provided with a plurality of ports; the first heat exchange assembly, the second heat exchange assembly, and the temperature control assembly each are connected to respective ports correspondingly, to change a flow direction of a refrigerant by switching of the core.

10. The liquid cooling unit according to claim 9, wherein in the second operation mode, the multi-way valve comprises a first multi-way valve and a second multi-way valve; one port of the first multi-way valve is connected to a liquid inlet of the first refrigeration assembly via a joint pipe; the second multi-way valve is arranged at the joint pipe, so that at least one of the first refrigeration assembly and the third refrigeration assembly is connected to the first heat exchange assembly in sequence to form respective loops by switching of the second multi-way valve.

11. The liquid cooling unit according to claim 10, wherein
the first multi-way valve is provided with a first port, a second port, a third port, a fourth port, a fifth port, a sixth port, a seventh port, and an eighth port;
the second multi-way valve is provided with a first liquid-inlet port, a first liquid outlet and a second liquid outlet;
the first port is connected to the liquid inlet of the first refrigeration assembly via the joint pipe;
the second multi-way valve is arranged at the joint pipe, the first liquid-inlet port is connected to the first port, the first liquid outlet is connected to a liquid inlet of the third refrigeration assembly, the second liquid outlet is connected to the liquid inlet of the first refrigeration assembly, so that at least one of the first refrigeration assembly and the third refrigeration assembly is connected to the first heat exchange assembly by switching-on/off each of the first liquid-inlet port, the first liquid outlet and the second liquid outlet.

12. The liquid cooling unit according to claim 3, wherein the first refrigeration assembly is a compression refrigeration assembly, the second refrigeration assembly is a first dry cooler assembly, and the third refrigeration assembly is a second dry cooler assembly.

13. The liquid cooling unit according to claim 12, wherein the compression refrigeration assembly comprises a condensation pipeline, a plate heat exchanger, a compressor, a first condenser, a first expansion valve, and a first heat exchange pipeline; wherein the plate heat exchanger, the compressor, the first condenser, and the first expansion valve are sequentially arranged at the condensation pipeline in a direction along which a condensation gas flows in the condensation pipeline and form a refrigeration circulation loop correspondingly; and the first heat exchange pipeline is connected to the plate heat exchanger and the multi-way valve to form a heat dissipation circulation loop.

14. The liquid cooling unit according to claim 12, wherein the liquid cooling unit is further provided with a fourth operation mode, the temperature control assembly further comprises a heater; wherein in the fourth operation mode, the heater is connected to the first heat exchange assembly and/or the second heat exchange assembly via the multi-way valve to achieve heating of a corresponding device to be temperature-controlled, so that the liquid cooling unit is allowed to switch between the first operation mode, the second operation mode, the third operation mode, and the fourth operation mode.

15. The liquid cooling unit according to claim 14, wherein the temperature control assembly comprises a heat pump assembly, wherein the heat pump assembly comprises a condensation end and an evaporation end, wherein the condensation end and the evaporation end each are provided with a heat exchange pipe connected to respective ports of the multi-way valve, wherein the condensation end is connected to the first heat exchange assembly and/or the second heat exchange assembly via the multi-way valve to form a heat pump heating loop; or
the evaporation end is connected to the first heat exchange assembly and/or the second heat exchange assembly via the multi-way valve to form a heat pump refrigeration loop, wherein the heat pump heating loop and the heat pump refrigeration loop are switchable to each other.

16. The liquid cooling unit according to claim 12, wherein the first dry cooler assembly comprises a first dry cooler liquid-inlet pipe, a first dry cooler body, and a first dry cooler liquid-outlet pipe; a liquid inlet of the first dry cooler liquid-inlet pipe is connected to a liquid outlet of the multi-way valve; a liquid outlet of the first dry cooler liquid-inlet pipe is connected to a liquid inlet of the first dry cooler body; a liquid outlet of the first dry cooler body is connected to a liquid inlet of the first dry cooler liquid-outlet pipe; and a liquid outlet of the first dry cooler liquid-outlet pipe is connected to a liquid inlet of the multi-way valve.

17. The liquid cooling unit according to claim 12, wherein the second dry cooler assembly comprises a second dry cooler liquid-inlet pipe, a second dry cooler body, and a second dry cooler liquid-outlet pipe; a liquid inlet of the second dry cooler liquid-inlet pipe is connected to a liquid outlet of the multi-way valve; a liquid outlet of the second dry cooler liquid-inlet pipe is connected to a liquid inlet of the second dry cooler body; a liquid outlet of the second dry cooler body is connected to a liquid inlet of the second dry cooler liquid-outlet pipe; and a liquid outlet of the second dry cooler liquid-outlet pipe is connected to a liquid inlet of the multi-way valve.

18. The liquid cooling unit according to claim 1, further comprising a condenser bypass assembly connected to the temperature control assembly.

19. The liquid cooling unit according to claim 3,
wherein the liquid cooling unit further comprises a first fan, wherein the first fan is arranged to correspond to each of respective evaporators, the first refrigeration assembly, the second refrigeration assembly, and the third refrigeration assembly; or
wherein the liquid cooling unit further comprises a first fan and a second fan, wherein the first fan is arranged to correspond to one of respective evaporators of the first refrigeration assembly, the second refrigeration assembly, and the third refrigeration assembly; and the second fan is arranged to correspond to other two of respective evaporators of the first refrigeration assembly, the second refrigeration assembly and the third refrigeration assembly; or
the liquid cooling unit further comprises a first fan, a second fan, and a third fan, which are arranged to correspond to the first refrigeration assembly, the second refrigeration assembly, and the third refrigeration assembly in one-to-one correspondence.

20. The liquid cooling unit according to claim 12, wherein a cut-off valve is arranged between at least one of the compression refrigeration assembly, the first dry cooler assembly, and the second dry cooler assembly, and the multi-way valve.

21. The liquid cooling unit according to claim 1, wherein
the first heat exchange assembly comprises a first heat exchange pipe, a first heat exchanger body, and a first pump body; both the first heat exchanger body and the first pump body are arranged at the first heat exchange pipe; and the first heat exchange pipe is circularly connected to the multi-way valve;
the second heat exchange assembly comprises a second heat exchange pipe, a second heat exchanger body, and a second pump body; both the second heat exchanger body and the second pump body are arranged at the second heat exchange pipe; and the second heat exchange pipe is circularly connected to the multi-way valve.

22. (canceled)

23. (canceled)

24. (canceled)

25. (canceled)

26. (canceled)
